(19) United States
(12) Patent Application Publication
(10) Pub. No.: US 2015/0207407 A1
(43) Pub. Date: Jul. 23, 2015

(54) Semiconductor Device, Semiconductor Module, and Electronic Circuit

(71) Applicant: Kabushiki Kaisha Toshiba, Tokyo (JP)

(72) Inventor: Tatsuya Nishiwaki, Komatsu-shi (JP)

(73) Assignee: KABUSHIKI KAISHA TOSHIBA, Minato-Ku, Tokyo (JP)

(21) Appl. No.: 14/327,001

(22) Filed: Jul. 9, 2014

(30) Foreign Application Priority Data
Jan. 20, 2014 (JP) 2014-007506

(51) Int. Cl. H02M 3/158; H01L 27/06; H02M 1/08; H01L 23/34

(52) U.S. Cl. CPC H02M 3/158; H01L 23/34; H01L 27/0629; H02M 1/08

(57) ABSTRACT

According to one embodiment, in semiconductor device, first semiconductor region is provided between first electrode and second electrode. Second semiconductor region is provided between first semiconductor region and second electrode. Third semiconductor region is provided between second semiconductor region and second electrode. Third electrode is in contact with first semiconductor region, second semiconductor region, and third semiconductor region via insulating film. Element part is configured to detect heat released from at least one of first semiconductor region, second semiconductor region, and third semiconductor region. Fourth semiconductor region is provided between first semiconductor region and second electrode. Fifth semiconductor region is provided between fourth semiconductor region and second electrode. And fourth electrode is in contact with first semiconductor region, fourth semiconductor region, and fifth semiconductor region via insulating film.

### CROSS-REFERENCE TO RELATED APPLICATIONS

This application is based upon and claims the benefit of priority from Japanese Patent Application No. 2014-007506, filed on Jan. 20, 2014; the entire contents of which are incorporated herein by reference.

### FIELD

Embodiments described herein relate generally to a semiconductor device, a semiconductor module, and an electronic circuit.

### BACKGROUND

In a voltage converter (e.g., DC-DC converter) using switching elements such as transistors, its conversion efficiency (ratio of output to input) is maximized at a certain output current and decreased at other output currents. One of the reasons is that in the region of small output current, the switching loss and the gate drive loss of the switching element are higher relative to the output power. On the other hand, in the region of large output current, the conduction loss due to the on-resistance of the switching element becomes higher. Thus, the switching element needs to be designed so as to optimize the conversion efficiency at a certain output current.

However, in the case of using the voltage converter with the output current varied, the optimal device design condition may be shifted depending on the output current.

### BRIEF DESCRIPTION OF THE DRAWINGS

FIG. 1A is an electronic circuit diagram according to a first embodiment, FIG. 1B is a timing chart of the electronic circuit according to the first embodiment;

FIG. 2A is a schematic plan view of a semiconductor device according to the first embodiment, FIG. 2B is a schematic sectional view of the semiconductor device according to the first embodiment;

FIG. 3A is a schematic plan view of a first example of the semiconductor module according to the first embodiment, FIG. 3B is a schematic plan view of a second example of the semiconductor module according to the first embodiment;

FIG. 4A is a circuit diagram of the DC-DC converter, FIG. 4B shows a relationship between output current and conversion efficiency, FIG. 4C shows a relationship between active area and loss;

FIG. 5A is a schematic plan view of a first variation of the semiconductor device of the first embodiment, FIG. 5B is a schematic sectional view of the first variation of the semiconductor device of the first embodiment;

FIG. 6A is a schematic plan view of a second variation of the semiconductor device of the first embodiment, FIGS. 6B and 6C are schematic sectional views of the second variation of the semiconductor device of the first embodiment;

FIG. 7A is a schematic plan view of a semiconductor device of a second embodiment, FIG. 7B is a schematic sectional view of the semiconductor device of the second embodiment;

FIG. 8A is a schematic plan view of a first example of the semiconductor module according to the second embodiment, FIG. 8B is a schematic plan view of a second example of the semiconductor module according to the second embodiment, FIG. 8C is a schematic plan view of a third example of the semiconductor module according to the second embodiment;

FIG. 9A is an electronic circuit diagram according to a third embodiment, FIG. 9B is a timing chart of the electronic circuit according to the third embodiment;

FIG. 10 is an electronic circuit diagram according to a fourth embodiment;

FIGS. 11A and 11B are timing charts of the electronic circuit according to the fourth embodiment;

FIG. 12A is a schematic plan view of a first example of a semiconductor device according to the fourth embodiment, FIG. 12B is a schematic sectional view of the first example of the semiconductor device according to the fourth embodiment;

FIGS. 13A and 13B are schematic sectional views showing the operation of the first example of the semiconductor device according to the fourth embodiment;

FIG. 14A is a schematic plan view of a second example of the semiconductor device according to the fourth embodiment, FIG. 14B is a schematic sectional view of the second example of the semiconductor device according to the fourth embodiment;

FIG. 15A is an electronic circuit diagram according to a fifth embodiment, FIG. 15B is a timing chart of the electronic circuit according to the fifth embodiment;

FIG. 16A is an electronic circuit diagram of a first example according to a sixth embodiment, FIG. 16B is an electronic circuit diagram of a second example according to the sixth embodiment;

FIG. 17A is an electronic circuit diagram according to a seventh embodiment, FIG. 17B is a timing chart of the electronic circuit according to the seventh embodiment; and

FIG. 18A is an electronic circuit diagram according to an eighth embodiment, FIG. 18B is a timing chart of the electronic circuit according to the eighth embodiment.

### DETAILED DESCRIPTION

According to one embodiment, a semiconductor device includes: a first electrode; a second electrode; a first semiconductor region; a second semiconductor region; a third semiconductor region; a third electrode; an element part; a fourth semiconductor region; a fifth semiconductor region; and a fourth electrode.

The first semiconductor region of a first conductivity type is provided between the first electrode and the second electrode, and the first semiconductor region includes a first region and a second region.

The second semiconductor region of a second conductivity type is provided between the first semiconductor region and the second electrode in the first region.

The third semiconductor region of the first conductivity type is provided between the second semiconductor region and the second electrode, and the third semiconductor region has a higher impurity concentration than the first semiconductor region.

The third electrode is in contact with the first semiconductor region, the second semiconductor region, and the third semiconductor region via a first insulating film.

The element part is configured to detect heat released from at least one of the first semiconductor region, the second semiconductor region, and the third semiconductor region in the first region.

The fourth semiconductor region of the second conductivity type is provided between the first semiconductor region and the second electrode in the second region.

The fifth semiconductor region of the first conductivity type is provided between the fourth semiconductor region and the second electrode, and the fifth semiconductor region has a higher impurity concentration than the first semiconductor region.

And the fourth electrode is in contact with the first semiconductor region, the fourth semiconductor region, and the fifth semiconductor region via a second insulating film.

Embodiments will now be described with reference to the drawings. In the following description, like members are labeled with like reference numerals. The description of the members once described is omitted appropriately.

### First Embodiment

An electronic circuit according to a first embodiment is now described.

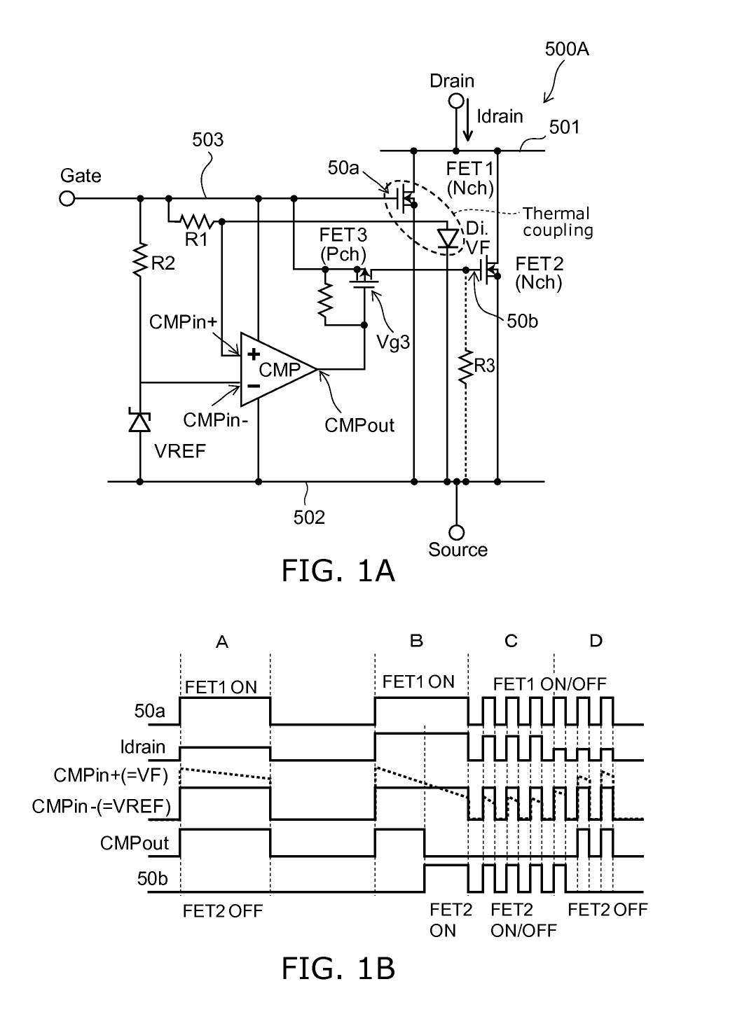

FIG. 1A is an electronic circuit diagram according to the first embodiment. FIG. 1B is a timing chart of the electronic circuit according to the first embodiment.

First, the configuration of the electronic circuit 500A according to the first embodiment is described.

The electronic circuit 500A includes a first wiring 501, a second wiring 502, a third wiring 503, a first switching element FET1, a second switching element FET2, a rectification element Di, a third switching element FET3, and a comparator CMP.

The first wiring (drain wiring) 501 is supplied with e.g. a drain potential (first potential). The second wiring (source wiring) 502 is supplied with a source potential (second potential) different from the drain potential. The source potential is lower than the drain potential. For instance, the source potential is a ground potential. The third wiring (gate wiring) 503 is supplied with a gate potential (third potential) different from the drain potential and the source potential.

The switching operation of the first switching element FET1 is controlled by its gate electrode 50a. The first switching element FET1 is e.g. an n-channel MOSFET (metal oxide semiconductor field effect transistor). The first switching element FET1 is connected between the first wiring 501 and the second wiring 502. The gate electrode 50a is connected to the third wiring 503. When the gate electrode 50a is supplied with a gate potential higher than or equal to a threshold voltage (Vth), the first switching element FET1 is turned on. This makes the path between the first wiring 501 and the second wiring 502 electrically continuous through the first switching element FET1.

The switching operation of the second switching element FET2 is controlled by its gate electrode 50b. The second switching element FET2 is e.g. an n-channel MOSFET. The second switching element FET2 is connected in parallel with the first switching element FET1 between the first wiring 501 and the second wiring 502.

The third switching element FET3 is connected between the third wiring 503 and the gate electrode 50b of the second switching element FET2. The switching operation of the third switching element FET3 is controlled by its gate electrode Vg3. The third switching element FET3 is e.g. a p-channel MOSFET.

When the third switching element FET3 is turned on, the gate electrode 50b of the second switching element FET2 is made electrically connected to the third wiring 503. When the gate electrode 50b is made electrically connected to the third wiring 503, the gate electrode 50b is supplied with a gate potential higher than or equal to the threshold voltage (Vth). This turns on the second switching element FET2. That is, the path between the first wiring 501 and the second wiring 502 is made electrically continuous through the second switching element FET2.

The rectification element Di (temperature sensing element) is e.g. a p-n diode including an anode electrode and a cathode electrode. The anode electrode of the rectification element Di is connected to the third wiring 503. The cathode electrode is connected to the second wiring 502. This rectification element Di is thermally coupled to the first switching element FET1. Here, the phrase “A is thermally coupled to B” means the state in which heat generated by “A” can be transferred to “B” by thermal conduction. For instance, the rectification element Di can detect heat released from at least one of the base region, the source region, and the drift region of the first switching element FET1 by its change in Vf.

The rectification element Di changes its forward voltage (Vf) due to heat generated by the first switching element FET1. In other words, the temperature of the first switching element FET1 can be sensed by detecting the forward voltage (Vf). Thus, the rectification element Di is also called a temperature detection diode.

In the electronic circuit 500A, when the temperature of the first switching element FET1 is lower than a prescribed value, the path between the first wiring 501 and the second wiring 502 is made electrically continuous through the first switching element FET1. When the temperature of the first switching element FET1 is higher than or equal to the prescribed value, the path between the first wiring 501 and the second wiring 502 is made electrically continuous through the first switching element FET1 and the second switching element FET2 (described later).

The comparator CMP (control element) senses the potential difference between the forward voltage (Vf) of the rectification element Di and a reference voltage. The potential of the gate electrode Vg3 of the third switching element FET3 changes depending on whether or not this potential difference is larger than or equal to a prescribed value. Accordingly, the third switching element FET3 is turned on or off. That is, the comparator CMP is a control element for controlling the switching operation of the third switching element FET3.

The reference voltage is generated by a reference voltage source VREF. The reference voltage source is desired to have stable characteristics against temperature change. Preferably, the reference voltage source is a thermal voltage source using the thermal voltage of a Zener diode, a diode, or an FET, or a bandgap reference voltage source. Furthermore, in the electronic circuit 500A, a resistor R1 is connected between the third wiring 503 and the rectification element Di, and a resistor R2 is connected between the third wiring 503 and the reference voltage source VREF. In the case where the threshold voltage of the second switching element FET2 is set relatively low, a pull-down resistor R3 may be connected between the gate electrode 50b of the second switching element FET2 and the second wiring 502. The electronic circuit 500A is provided in e.g. a semiconductor package, not shown.

Elements incorporated in the electronic circuit 500A are now described.

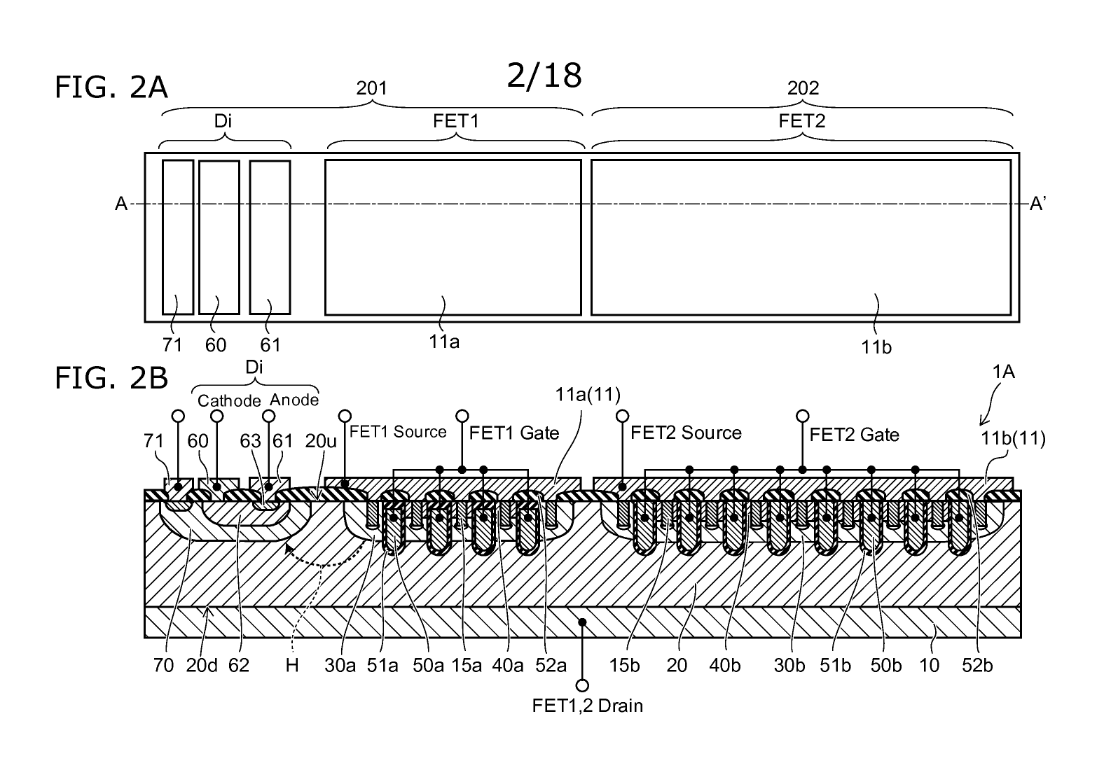

FIG. 2A is a schematic plan view of a semiconductor device according to the first embodiment. FIG. 2B is a schematic sectional view of the semiconductor device according to the first embodiment. Here, FIG. 2B shows a cross section taken along line A-A′ of FIG. 2A.

In the semiconductor device 1A shown in FIGS. 2A and 2B, the semiconductor layer 20 includes a first region 201 and a second region 202. The semiconductor device 1A is a composite semiconductor device including the aforementioned first switching element FET1 in the first region 201, the second switching element FET2 in the second region 202, and the rectification element Di. Here, the rectification element Di is provided in the first region 201. The semiconductor device 1A is what is called a semiconductor device of the vertical electrode structure, and includes a MOSFET of the trench gate structure. The semiconductor device 1A shown in the figures shows part of the inside of what is called a semiconductor chip. In the semiconductor device 1A, the area occupied by the first switching element FET1 is smaller than the area occupied by the second switching element FET2.

The semiconductor device 1A includes a drain electrode 10 (first electrode), a source electrode 11 (second electrode), a semiconductor layer 20 (first semiconductor region), a base region 30a (second semiconductor region), a source region 40a (third semiconductor region), a gate electrode 50a (third electrode), a base region 30b (fourth semiconductor region), a source region 40b (fifth semiconductor region), a gate electrode 50b (fourth electrode), and a rectification element Di (rectification element part).

The source electrode 11 is provided on the drain electrode 10. Here, the source electrode 11 includes a first electrode part 11a and a second electrode part 11b. The semiconductor layer 20 of n-type is provided between the drain electrode 10 and the source electrode 11. The semiconductor layer 20 is a drift region of the semiconductor device 1A. The semiconductor layer 20 has an upper surface 20u (first surface) and a lower surface 20d (second surface) on the opposite side of the upper surface 20u. The semiconductor layer 20 may be a semiconductor region 20.

The base region 30a is provided between the semiconductor layer 20 and the first electrode part 11a of the source electrode 11. The conductivity type of the base region 30a is p-type.

The source region 40a is provided between the base region 30a and the first electrode part 11a of the source electrode 11. The source region 40a is in contact with the first electrode part 11a. The conductivity type of the source region 40a is n⁺-type. The impurity concentration of the source region 40a is higher than the impurity concentration of the semiconductor layer 20.

The gate electrode 50a is in contact with the semiconductor layer 20, the base region 30a, and the source region 40a via a gate insulating film 51a (first insulating film). An interlayer insulating film 52a is provided between the gate electrode 50a and the first electrode part 11a of the source electrode 11. The semiconductor device 1A includes a plurality of gate electrodes 50a.

The first switching element FET1 includes the first electrode part 11a of the source electrode 11, the drain electrode 10 below the first electrode part 11a, the semiconductor layer 20 between the first electrode part 11a and the drain electrode 10, the base region 30a, the source region 40a, the gate electrode 50a and the like.

The base region 30b is provided in a region different from the region provided with the base region 30a. The base region 30b is provided between the semiconductor layer 20 and the second electrode part 11b of the source electrode 11. The conductivity type of the base region 30b is p-type. The base region 30a and the base region 30b may be continuously connected between the semiconductor layer 20 and the source electrode 11. This also applies to the semiconductor devices illustrated later.

The source region 40b is provided between the base region 30b and the second electrode part 11b of the source electrode 11. The source region 40b is in contact with the second electrode part 11b. The conductivity type of the source region 40b is n⁺-type. The impurity concentration of the source region 40b is higher than the impurity concentration of the semiconductor layer 20. The source region 40a and the source region 40b may be provided in the connected base region 30a, 30b.

The gate electrode 50b is in contact with the semiconductor layer 20, the base region 30b, and the source region 40b via a gate insulating film 51b (second insulating film). An interlayer insulating film 52b is provided between the gate electrode 50b and the second electrode part 11b of the source electrode 11. The semiconductor device 1A includes a plurality of gate electrodes 50b.

The second switching element FET2 includes the second electrode part 11b of the source electrode 11, the drain electrode 10 below the second electrode part 11b, the semiconductor layer 20 between the second electrode part 11b and the drain electrode 10, the base region 30b, the source region 40b, the gate electrode 50b and the like.

The first switching element FET1 and the second switching element FET2 share the semiconductor layer 20. The first switching element FET1 is provided in the first region 201 of the semiconductor layer 20. The second switching element FET2 is provided in the second region 202 of the semiconductor layer 20. Each of the first switching element FET1 and the second switching element FET2 includes a gate electrode, and are independently controlled by the respective gate electrodes.

FIG. 2B shows the source electrode 11 divided into two parts (first electrode part 11a, second electrode part 11b), and the base region 30a, 30b which are divided into two parts. However, the embodiment also encompasses a structure in which these are not divided. This is because the first switching element FET1 and the second switching element FET2 are connected in parallel between the drain and the source.

Furthermore, the semiconductor device 1A includes p⁺-type contact regions 15a, 15b functioning as hole extraction layers. The contact region 15a is provided between the adjacent gate electrodes 50a. The contact region 15b is provided between the adjacent gate electrodes 50b. The upper end of the contact region 15a is connected to the first electrode part 11a of the source electrode 11. The lower end of the contact region 15a is in contact with the base region 30a. The upper end of the contact region 15b is connected to the second electrode part 11b of the source electrode 11. The lower end of the contact region 15b is in contact with the base region 30b.

Furthermore, in the semiconductor device 1A, the rectification element Di is provided on the semiconductor layer 20. The rectification element Di includes a cathode electrode 60 (fifth electrode), an anode electrode 61 (sixth electrode), an n-type semiconductor region 62 (sixth semiconductor region), and a p-type semiconductor region 63 (seventh semiconductor region).

The n-type semiconductor region 62 is provided from the upper surface 20u toward the lower surface 20d of the semiconductor layer 20. The p-type semiconductor region 63 is provided from the upper surface 20u toward the lower surface 20d of the semiconductor layer 20. The n-type semiconductor region 62 is provided below the p-type semiconductor region 63. The p-type semiconductor region 63 is in contact with the n-type semiconductor region 62. The p-type semiconductor region 63 and the n-type semiconductor region 62 form a p-n junction. The n-type semiconductor region 62 is electrically connected to the cathode electrode 60. The p-type semiconductor region 63 is electrically connected to the anode electrode 61.

The distance between the rectification element Di and the first switching element FET1 is shorter than the distance between the rectification element Di and the second switching element FET2 (second region). In other words, the distance between the first region 201 and the rectification element Di is shorter than the distance between the second region 202 and the rectification element Di. That is, the rectification element Di is placed nearer to the first switching element FET1 (first region) than to the second switching element FET2.

Here, the rectification element Di placed near the first switching element FET1 is thermally coupled to the first switching element FET1. That is, the rectification element Di is thermally coupled to at least one of the semiconductor layer 20 located between the drain electrode 10 and the base region 30a, the base region 30a, and the source region 40a. The temperature of the rectification element Di changes under the influence of heat generated by the first switching element FET1. For instance, in FIG. 2B, conduction of heat from the first switching element FET1 to the rectification element Di is indicated by arrow H.

A p-type semiconductor region 70 shaped like a well is provided below the rectification element Di. The p-type semiconductor region 70 is in contact with an electrode 71, and is connected to the source electrode 11 through the electrode 71. This ensures insulation between the rectification element Di and the switching element FET1, FET2.

In the embodiment, a primary component of each of the semiconductor layer 20, the base region 30a, 30b, the source region 40a, 40b, and the rectification element Di is e.g. silicon (Si). The impurity element of the conductivity type such as n⁺-type and n-type (first conductivity type) can be e.g. phosphorus (P), arsenic (As) or the like. The impurity element of the conductivity type such as p⁺-type and p-type (second conductivity type) can be e.g. boron (B) or the like.

The base region 30a, 30b and the p-type semiconductor region 63 are formed by e.g. implantation of the impurity element of the second conductivity type into the semiconductor layer 20 followed by heating. The source region 40a, 40b is formed by e.g. implantation of the impurity element of the first conductivity type into the base region 30a, 30b followed by heating. The p-type semiconductor region 70 is formed by e.g. implantation of the impurity element of the second conductivity type into the semiconductor layer 20 followed by heating. The n-type semiconductor region 62 is formed by e.g. implantation of the impurity element of the first conductivity type into the p-type semiconductor region 70 followed by heating. The p-type semiconductor region 63 is formed by e.g. implantation of the impurity element of the second conductivity type into the n-type semiconductor region 62 followed by heating. The material of the semiconductor may be silicon carbide (SiC), gallium nitride (GaN) or the like instead of silicon (Si).

The structure of the semiconductor device is not limited to the trench gate structure, but may be of the planar gate structure. Furthermore, the structure of the semiconductor device is not limited to the structure in which the source electrode and the drain electrode are vertically placed in the semiconductor layer 20. The embodiment also encompasses a structure in which the source electrode and the drain electrode are laterally arranged above the semiconductor layer 20.

A semiconductor module incorporated in the electronic circuit 500A is now described.

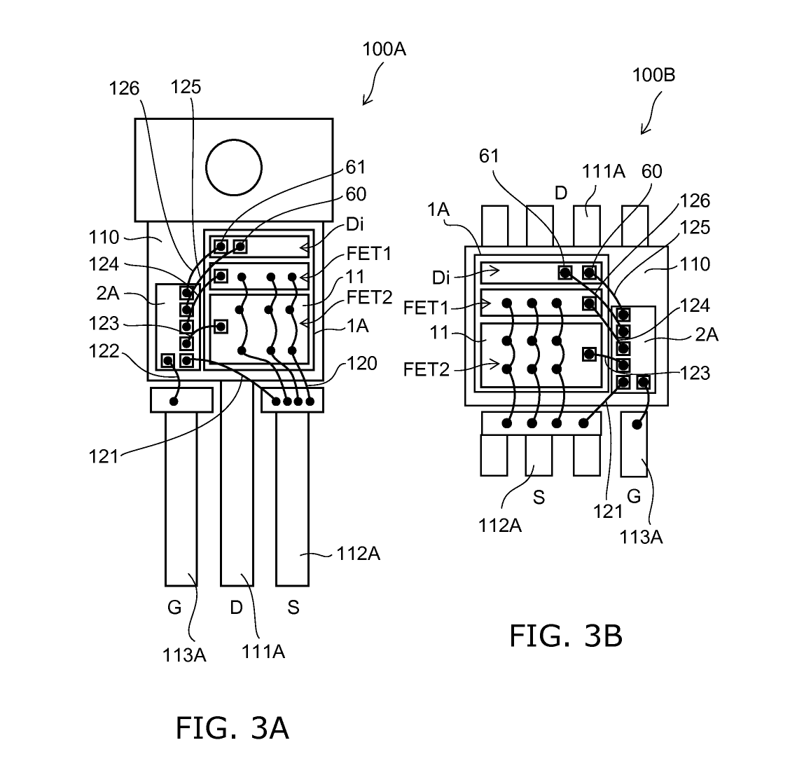

FIG. 3A is a schematic plan view of a first example of the semiconductor module according to the first embodiment. FIG. 3B is a schematic plan view of a second example of the semiconductor module according to the first embodiment.

The semiconductor module 100A includes a conductive substrate 110 as an example of a support substrate, a semiconductor device 1A, an analog control chip 2A, a first electrode terminal 111A, a second electrode terminal 112A, and a third electrode terminal 113A.

The semiconductor device 1A is mounted on the conductive substrate 110 so that the drain electrode 10 of the semiconductor device 1A is electrically connected to the conductive substrate 110. The first electrode terminal 111A is electrically connected to the conductive substrate 110. The second electrode terminal 112A is electrically connected to the source electrode 11 of the semiconductor device 1A through a wiring (bonding wire) 120. The second electrode terminal 112A is connected to the analog control chip 2A through a wiring 121.

The third electrode terminal 113A is electrically connected to the gate electrode 50a of the semiconductor device 1A through wirings 122, 123. The third electrode terminal 113A can be electrically connected to the gate electrode 50b of the semiconductor device 1A through wirings 122, 124. The cathode electrode 60 of the rectification element Di in the semiconductor device 1A is connected to the second electrode terminal 112A through wirings 121, 125. The anode electrode 61 of the rectification element Di is connected to the third electrode terminal 113A through wirings 122, 126.

The analog control chip 2A includes the third switching element FET3, the comparator CMP, the resistor R1, the resistor R2, and the reference voltage source VREF in the electronic circuit 500A.

The first electrode terminal 111A is connected to the first wiring 501 of the electronic circuit 500A. The second electrode terminal 112A is connected to the second wiring 502 of the electronic circuit 500A. The third electrode terminal 113A is connected to the third wiring 503 of the electronic circuit 500A.

The semiconductor module 100A shown in FIG. 3A shows a structure in which the semiconductor device 1A and the analog control chip 2A are separated on the conductive substrate 110. However, the semiconductor device 1A and the analog control chip 2A may be integrated into one chip, and the chip may be mounted on the conductive substrate 110.

In the semiconductor module 100A, the first electrode terminal 111A, the second electrode terminal 112A, and the third electrode terminal 113A extend in the same direction and are juxtaposed. However, the semiconductor module 100A is not limited to such configuration. For instance, as in the semiconductor module 100B shown in FIG. 3B, the second electrode terminal 112A and the third electrode terminal 113A may be placed on the opposite side of the first electrode terminal 111A.

The semiconductor module 100A, 100B is provided with a MOSFET of the three-terminal structure including a source terminal, a drain terminal, and a gate terminal. This MOSFET is compatible with the conventional MOSFET of the three-terminal structure. Here, compatibility is achieved also in the case of using an IGBT (described later) instead of the MOSFET.

Before describing the operation of the electronic circuit 500A and the semiconductor device 1A according to the first embodiment, the relationship between the output current and the conversion efficiency of a typical DC-DC converter is described. Here, the conversion efficiency is represented by e.g. the ratio of the output power to the input power. The switching element of the DC-DC converter is a typical MOSFET.

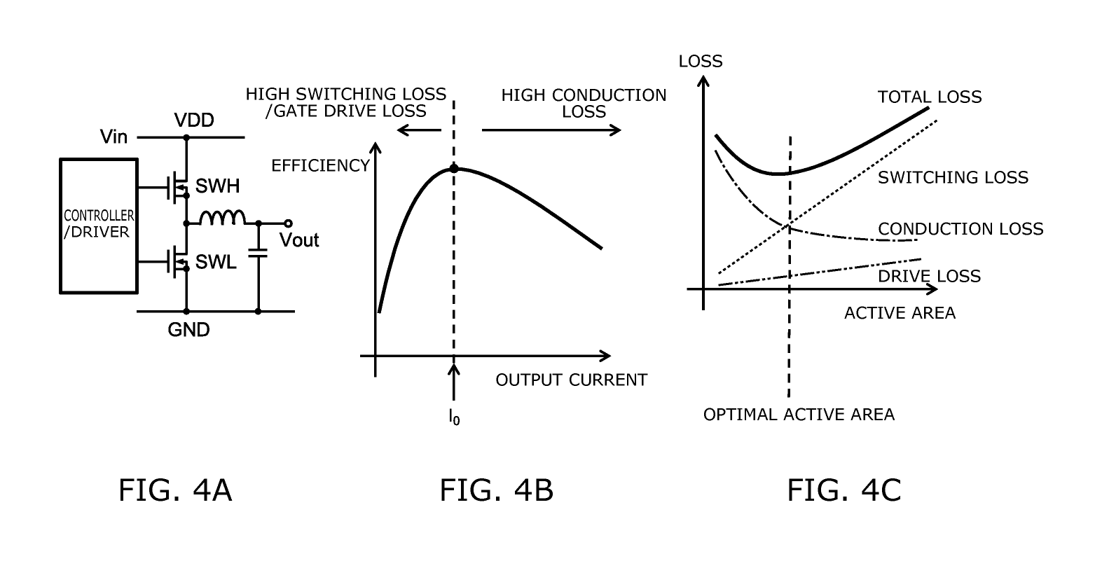

FIG. 4A is a circuit diagram of the DC-DC converter. FIG. 4B shows a relationship between output current and conversion efficiency. FIG. 4C shows a relationship between active area and loss.

The DC-DC converter shown in FIG. 4A includes a high-side switching element SWH and a low-side switching element SWL. Here, the switching elements SWH, SWL include e.g. a MOSFET.

As shown in FIG. 4B, the conversion efficiency is maximized at a certain output current value I₀. Here, the conversion efficiency becomes lower irrespective of whether the output current is smaller or larger than the output current value I₀. The reason for this is as follows. In the region where the output current is smaller than the output current value I₀, the switching loss and the gate drive loss of the MOSFET are higher relative to the output power. On the other hand, in the region where the output current is larger than the output current value I₀, the conduction loss due to the on-resistance of the MOSFET becomes higher. In the circuit design of a DC-DC converter, an optimal MOSFET is designed so as to maximize the conversion efficiency for a required output current. The concept is shown in FIG. 4C.

FIG. 4C shows a relationship between the active area (the area of the active region) and the conduction loss of MOSFETs. Here, the MOSFETs are assumed to be of the same cell structure. Furthermore, the output current value and the operating frequency are set to prescribed values. Here, the total conduction loss is determined by e.g. the sum of switching loss, conduction loss, and gate drive loss.

The on-resistance of the switching element typically decreases with the increase in active area. Thus, the conduction loss decreases in inverse proportion to the active area. On the other hand, the switching charge (Qsw) typically increases with the increase in active area. Thus, the switching time increases, and the switching loss linearly increases with the active area. Here, the gate drive current is assumed to be constant. Furthermore, the gate drive loss also increases with the increase in active area. In the circuit design of a DC-DC converter, an optimal active area is determined so as to minimize the total loss.

However, when the output current is changed, the relationship between active area and conduction loss changes depending on the output current. Thus, even if an optimal active area is determined for a certain output current value, the active area is not necessarily optimal for other output current values. That is, it is difficult to realize a highly efficient circuit in a wide range of output current.

A method for addressing this problem is to change the active area by parallel connection between the drain and the source of the MOSFET in the semiconductor chip to switch the gate of the MOSFET. This method can achieve an optimal active area even if the output current value is changed. However, in this method, the switching is controlled by an external controller provided outside the semiconductor chip. Furthermore, this method may require a gate driver for adjusting the number of elements to be operated by detecting the output current.

In contrast, an external controller or a gate driver is not required in the first embodiment. In the first embodiment, the magnitude of the load of the switching element is detected, and the active area of the element is changed depending on the magnitude of the load. That is, the first embodiment can realize a highly efficient circuit in a wide range of output current without requiring an external controller or a gate driver. In the following, the operation of the electronic circuit 500A according to the first embodiment is described.

The operation of the electronic circuit 500A according to the first embodiment is described in more detail with reference to FIGS. 1A and 1B. With regard to the semiconductor module, the semiconductor module 100A is taken as an example.

The gate electrode 50a of the first switching element FET1 shown in FIG. 1A is applied with a voltage higher than or equal to the threshold voltage (Vth). Then, the first switching element FET1 is turned on. Thus, a current (hereinafter referred to as drain current) flows between the source and the drain of the first switching element FET1. Here, the second switching element FET2 and the third switching element FET3 are in the off-state. In FIG. 1B, the period of this state is shown as period A. At this stage, the load on the first switching element FET1 is light, and the drain current is relatively small. In this case, the second switching element FET2 and the third switching element FET3 are in the off-state, and only the first switching element FET1 is operated.

Next, when the load on the first switching element FET1 becomes heavier and increases the drain current, the first switching element FET1 generates heat by the conduction loss due to the on-resistance of the first switching element FET1. In FIG. 1B, the period of this state is shown as period B.

Here, Vf (forward voltage) of the rectification element (temperature detection diode) Di has a temperature coefficient of −2.0 to −2.5 mV/° C. if the semiconductor component of the rectification element Di is composed primarily of silicon (Si).

The element temperature of the first switching element FET1 increases with the increase in the drain current of the first switching element FET1. Then, the temperature of the rectification element Di increases, and Vf decreases. In other words, the drain current can be detected by sensing Vf. Here, it is assumed that the source line of the electronic circuit 500A is grounded. Thus, the decrease of Vf means the decrease of the anode voltage applied to the rectification element Di (anode application voltage).

The anode voltage of the rectification element Di is compared with the reference voltage source VREF by the comparator CMP. For instance, the comparator CMP receives the voltage from the reference voltage source VREF as an inverting input (in−), and the anode voltage of the rectification element Di as a non-inverting input (in+).

If the difference between the reference voltage source VREF and the anode voltage of the rectification element Di is larger than a prescribed value (e.g., Δ0 V), a voltage is outputted from the comparator CMP and applied to the gate electrode Vg3 of the third switching element FET3. In this case, even if the gate electrode Vg3 is supplied with the voltage, the third switching element FET3 is in the off-state because it is a p-channel MOSFET.

However, the temperature of the rectification element Di increases with the increase in the element temperature of the first switching element FET1. Then, the anode voltage of the rectification element Di decreases. Subsequently, the anode voltage of the rectification element Di continues to decrease. When the difference between the reference voltage source VREF and the anode voltage of the rectification element Di becomes smaller than the prescribed value, the comparator CMP ceases to produce the output.

Thus, voltage supply to the gate electrode Vg3 of the third switching element FET3 is stopped. This turns on the third switching element FET3.

Thus, the gate electrode 50b of the second switching element FET2 is supplied with a potential higher than or equal to the threshold. This turns on the second switching element FET2. That is, the path between the first wiring 501 and the second wiring 502 is made electrically continuous also through the second switching element FET2.

That is, in the state in which the load on the first switching element FET1 is heavier, the gate electrode 50b of the second switching element FET2 is also applied with a voltage. Thus, the second switching element FET2 is also turned on. Accordingly, the first switching element FET1 and the second switching element FET2 connected in parallel are both turned on. This increases the element area. Thus, the on-resistance of the semiconductor module 100A decreases. As a result, the conduction loss of the semiconductor module 100A is reduced.

Thus, in the semiconductor module 100A, when the first switching element FET1 is subjected to a light load, only the first switching element FET1 is operated. This reduces the switching loss and the drive loss of the semiconductor module 100A. Furthermore, when the first switching element FET1 is subjected to a heavy load, the first switching element FET1 and the second switching element FET2 are operated. This decreases the on-resistance of the semiconductor module 100A. Thus, the conduction loss of the semiconductor module 100A is reduced.

Next, the dynamic operation of the electronic circuit 500A is described.

The period C shown in FIG. 1B shows the switching operation of the first switching element FET1 under heavy load. When the first switching element FET1 is subjected to switching operation at high speed, the switching time is shorter than the time taken for the decrease of the temperature of the first switching element FET1. Thus, the temperature of the first switching element FET1 remains at a temperature higher than or equal to a certain reference temperature. Thus, the second switching element FET2 connected in parallel with the first switching element FET1 is also subjected to switching operation.

The correlation between the element temperature and the drain current can be utilized to indirectly monitor the drain current by the element temperature. That is, the electronic circuit 500A has a memory function (memory operation means) capable of successively storing the most recent drain current by detecting the element temperature.

There is a method for measuring the drain current within the time of the switching pulse to switch the number of MOSFETs operated in parallel in an extremely short time as a method for detecting the drain current in real time. In this method, the switching frequency is limited by the operating speed of the control circuit. Thus, the operating current at the most recent switching time needs to be stored by using a logic circuit in an external controller. Furthermore, the number of MOSFETs operated in parallel needs to be switched with a span (time interval) longer than the switching pulse cycle. Moreover, the drain current is easily superimposed by noise due to switching. This may make it difficult to accurately measure the drain current value in real time.

In contrast, the drain current detection by the element temperature of the first embodiment utilizes a technique for sensing heat released from the first switching element FET1. This eliminates the need of a complex logic circuit. For instance, in the first embodiment, heat is detected by the rectification element Di using heat capacity in the semiconductor package. Thus, the average value of the operating current can be sensed. Furthermore, the technique of heat sensing has an advantage that the drain current, that is, the heat is not easily superimposed by noise.

The period D shown in FIG. 1B shows the switching operation of the first switching element FET1 under light load. In this case, even if the first switching element FET1 is subjected to switching operation at high speed, the switching time is longer than the time taken for the decrease of the temperature of the first switching element FET1. This maintains the temperature of the first switching element FET1 at a temperature lower than the reference temperature. Thus, the second switching element FET2 maintains its off-state.

Thus, the first embodiment realizes a semiconductor device, a semiconductor module, and an electronic circuit realizing high conversion efficiency in a wide range of output current.

### First Variation of the First Embodiment

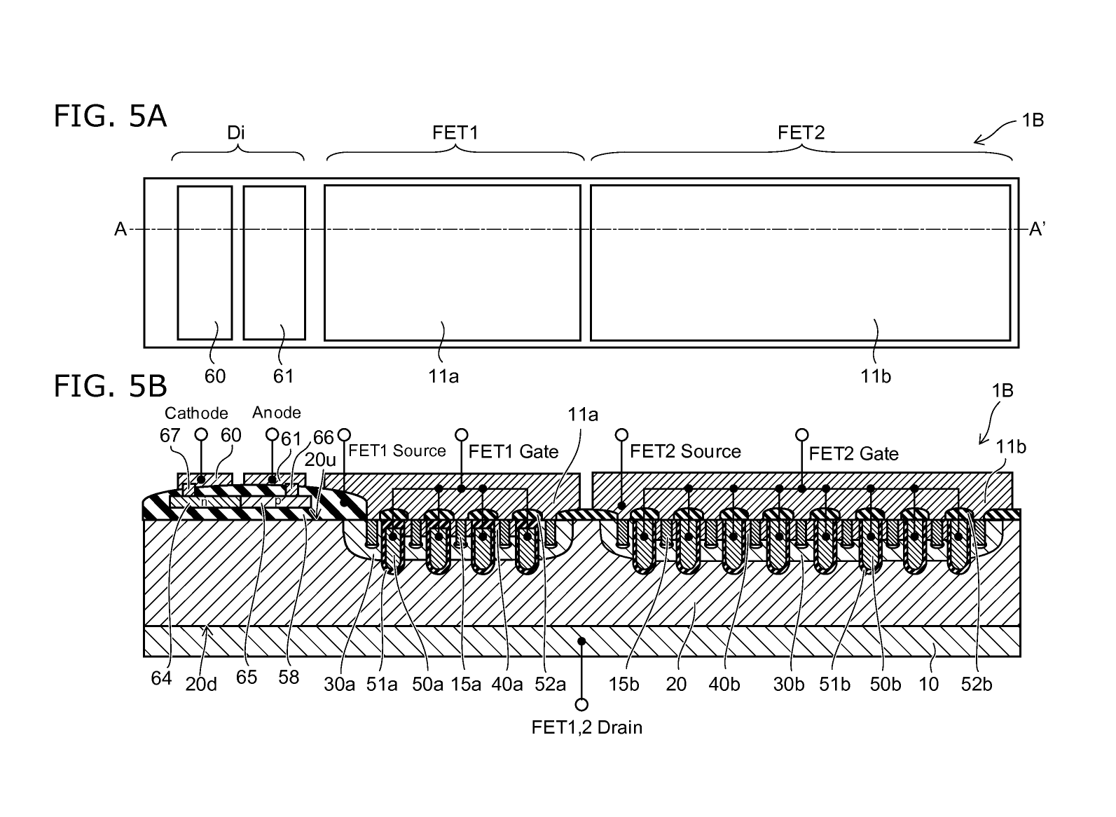

FIG. 5A is a schematic plan view of a first variation of the semiconductor device of the first embodiment. FIG. 5B is a schematic sectional view of the first variation of the semiconductor device of the first embodiment. Here, FIG. 5B shows a cross section taken along line A-A′ of FIG. 5A.

In the semiconductor device 1B, the rectification element Di includes an n-type semiconductor region 64, a p-type semiconductor region 65, a cathode electrode 60, and an anode electrode 61. The rectification element Di of the semiconductor device 1B is thermally coupled to the first switching element FET1.

The n-type semiconductor region 64 and the p-type semiconductor region 65 are provided above the upper surface 20u of the semiconductor layer 20. The material of the n-type semiconductor region 64 and the p-type semiconductor region 65 is composed primarily of polysilicon. The cathode electrode 60 is connected to the n-type semiconductor region 64 through a contact 67. The anode electrode 61 is connected to the p-type semiconductor region 65 through a contact 66. The n-type semiconductor region 64 and the p-type semiconductor region 65 are surrounded with an insulating layer 58 provided on the upper surface 20u of the semiconductor layer 20. The n-type semiconductor region 64 and the p-type semiconductor region 65 are provided in the insulating layer 58.

In the semiconductor device 1B, the n-type semiconductor region 64 and the p-type semiconductor region 65 are insulated from the semiconductor layer 20 by the insulating layer 58. Thus, no parasitic diode exists between the rectification element and the first switching element FET1. Accordingly, the semiconductor device 1B has a higher breakdown voltage between the rectification element and the first switching element FET1 than the semiconductor device 1A. This suppresses leakage between the rectification element and the first switching element FET1.

### Second Variation of the First Embodiment

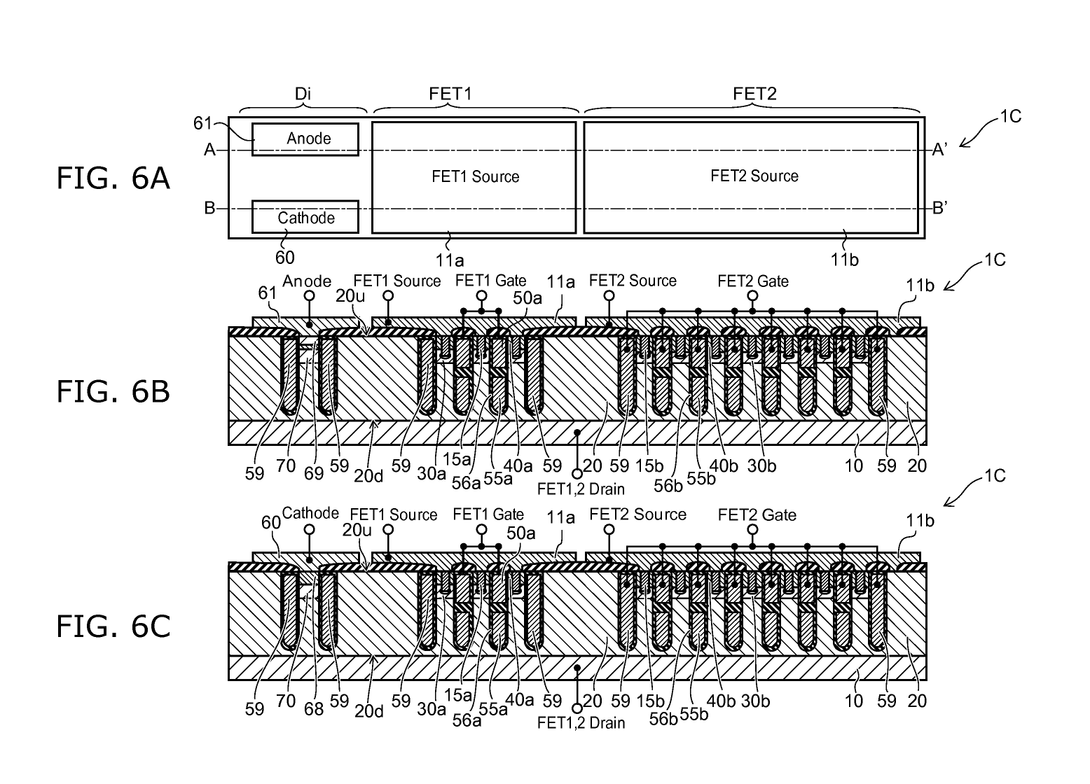

FIG. 6A is a schematic plan view of a second variation of the semiconductor device of the first embodiment. FIGS. 6B and 6C are schematic sectional views of the second variation of the semiconductor device of the first embodiment. Here, FIG. 6B shows a cross section taken along line A-A′ of FIG. 6A. FIG. 6C shows a cross section taken along line B-B′ of FIG. 6A.

In the semiconductor device 1C, a field plate electrode 55a (seventh electrode) is provided between the gate electrode 50a and the drain electrode 10. The field plate electrode 55a is in contact with the semiconductor layer 20 via a field plate insulating film (third insulating film) 56a. Furthermore, a field plate electrode 55b (eighth electrode) is provided between the gate electrode 50b and the drain electrode 10. The field plate electrode 55b is in contact with the semiconductor layer 20 via a field plate insulating film (fourth insulating film) 56b. The field plate electrode 55b is electrically connected to the source electrode 11 or the gate electrode 50.

In the semiconductor device 1C, the rectification element Di is provided on the semiconductor layer 20. The rectification element Di includes an n-type semiconductor region 68, a p-type semiconductor region 69, a cathode electrode 60, and an anode electrode 61. The rectification element Di of the semiconductor device 1C is thermally coupled to the first switching element FET1.

The p-type semiconductor region 69 is provided from the upper surface 20u toward the lower surface 20d of the semiconductor layer 20. The n-type semiconductor region 68 is provided from the upper surface 20u toward the lower surface 20d of the semiconductor layer 20. The n-type semiconductor region 68 is provided below the p-type semiconductor region 69. The p-type semiconductor region 69 is in contact with the n-type semiconductor region 68. The p-type semiconductor region 69 and the n-type semiconductor region 68 form a p-n junction. The n-type semiconductor region 68 is electrically connected to the cathode electrode 60. The p-type semiconductor region 69 is electrically connected to the anode electrode 61. A p-type semiconductor region 70 is provided below the rectification element Di. The p-type semiconductor region 70 is electrically connected to the source electrode 11.

A plurality of gate electrodes 50a are sandwiched between a pair of electrodes 59. A plurality of gate electrodes 50b are sandwiched between a pair of electrodes 59. The n-type semiconductor region 68 and the p-type semiconductor region 69 are sandwiched between a pair of electrodes 59.

In the semiconductor device 1C, the field plate electrode 55a is provided below the gate electrode 50a, and the field plate electrode 55b is provided below the gate electrode 50b. Thus, when the semiconductor device 1C is in the off-state, the depletion layer easily spreads in the semiconductor layer 20 and improves the breakdown voltage. Furthermore, because the depletion layer easily spreads in the semiconductor layer 20, the impurity concentration of the semiconductor layer 20 can be set higher than the impurity concentration of the semiconductor layer 20 of the semiconductor devices 1A, 1B. Thus, the resistivity of the semiconductor layer 20 is decreased. This further decreases the on-resistance of the semiconductor device 1C.

Preferably, the rectification element Di is also of the trench field plate structure in order to ensure the breakdown voltage between the rectification element Di on one hand and the first switching element FET1 and the second switching element FET2 on the other.

In the semiconductor devices 1A-1C, each element area of the first switching element FET1 and the second switching element FET2 may be designed so that the element area of the second switching element FET2 is larger than the element area of the first switching element FET1. This minimizes the switching loss and the drive loss in the period when only the first switching element FET1 is operated. The on-resistance of the semiconductor device 1A-1C is significantly reduced in the period when the first switching element FET1 and the second switching element FET2 are operated in parallel.

### Second Embodiment

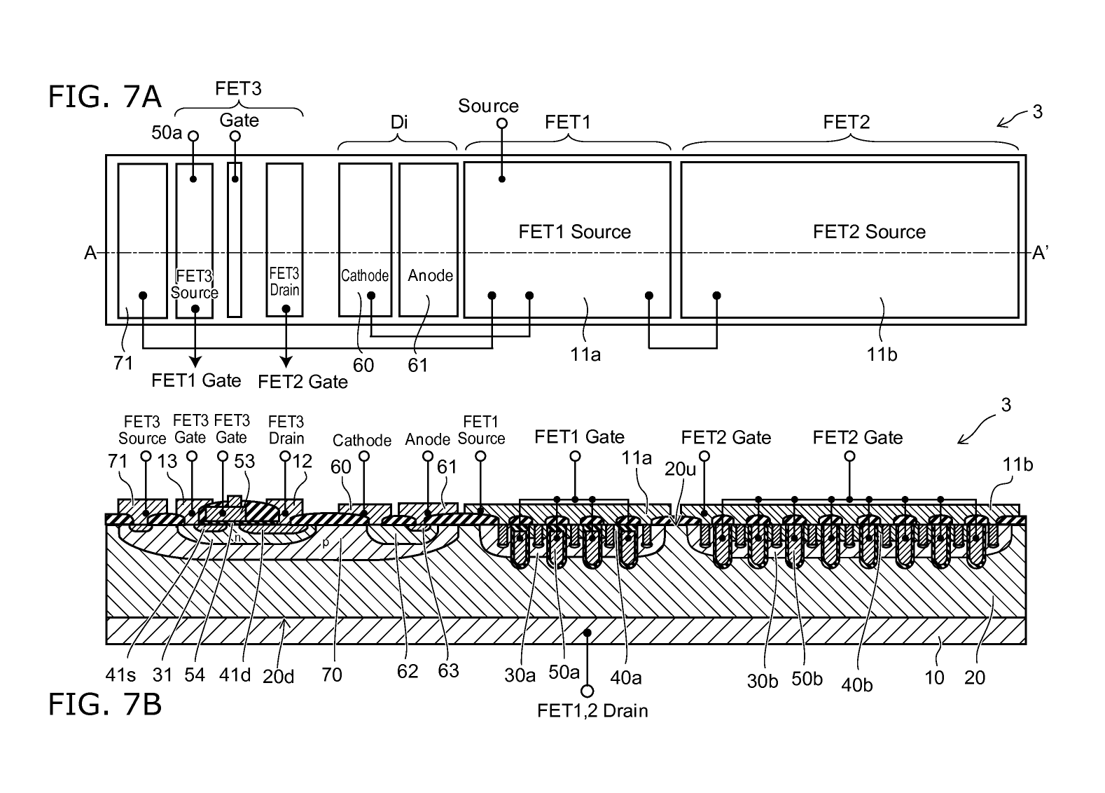

FIG. 7A is a schematic plan view of a semiconductor device of a second embodiment. FIG. 7B is a schematic sectional view of the semiconductor device of the second embodiment. Here, FIG. 7B shows a cross section taken along line A-A′ of FIG. 7A.

The third switching element FET3 may be incorporated in the semiconductor device 3 rather than in the analog control chip.

In the semiconductor device 3, an n-type base region 31 (eighth semiconductor region) is provided from the upper surface 20u toward the lower surface 20d of the semiconductor layer 20. A p⁺-type source region 41s (ninth semiconductor region) and a p⁺-type drain region 41d (tenth semiconductor region) are provided on the base region 31. The impurity concentration of the source region 41s and the drain region 41d is higher than the impurity concentration of the base region 30a, 30b.

A source electrode 13 (ninth electrode) is electrically connected to the source region 41s. A drain electrode 12 (tenth electrode) is electrically connected to the drain region 41d. A gate electrode 53 (eleventh electrode) is in contact with the base region 31, the source region 41s, and the drain region 41d via a gate insulating film 54 (fifth insulating film).

The third switching element FET3 includes the source electrode 13, the drain electrode 12, the base region 31, the source region 41s, the drain region 41d, the gate electrode 53 and the like. Thus, the third switching element FET3 has e.g. a planar gate structure. The third switching element FET3 is a p-channel MOSFET.

The source electrode 13 is electrically connected to the gate electrode 50a of the first switching element FET1. The drain electrode 12 is electrically connected to the gate electrode 50b of the second switching element FET2. The gate electrode 53 is connected to the output part of the comparator CMP.

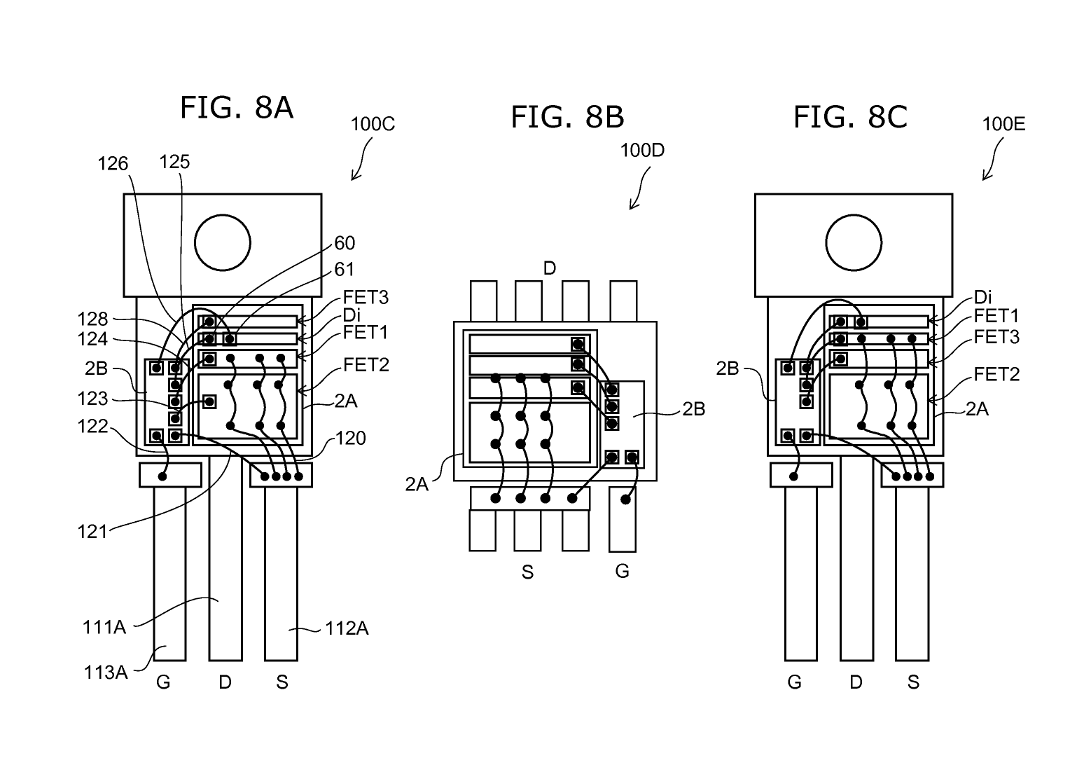

FIG. 8A is a schematic plan view of a first example of the semiconductor module according to the second embodiment. FIG. 8B is a schematic plan view of a second example of the semiconductor module according to the second embodiment. FIG. 8C is a schematic plan view of a third example of the semiconductor module according to the second embodiment.

In the semiconductor module 100C, the semiconductor device 3 is mounted on the conductive substrate 110 so that the drain electrode 10 of the semiconductor device 3 is electrically connected to the conductive substrate 110.

The second electrode terminal 112A is electrically connected to the source electrode 11 of the semiconductor device 3 through a wiring 120. The second electrode terminal 112A is connected to the analog control chip 2B through a wiring 121.

The third electrode terminal 113A is electrically connected to the gate electrode 50a of the semiconductor device 3 through wirings 122, 123. The third electrode terminal 113A can be electrically connected to the gate electrode 50b of the semiconductor device 3 through wirings 122, 124. The cathode electrode 60 of the rectification element Di in the semiconductor device 3 is connected to the second electrode terminal 112A through wirings 121, 125. The anode electrode 61 of the rectification element Di is connected to the third electrode terminal 113A through wirings 122, 126.

The gate electrode 53 of the third switching element FET3 is connected to the output side of the comparator CMP in the analog control chip 2B through a wiring 128. Besides, the source electrode 13 of the third switching element FET3 is electrically connected to the gate electrode 50a of the first switching element FET1 through a wiring (not shown). The drain electrode 12 of the third switching element FET3 is electrically connected to the gate electrode 50b of the second switching element FET2 through a wiring (not shown). Here, the wiring not shown is not a bonding wire, but e.g. an internal wiring routed in the semiconductor device 3.

The analog control chip 2B includes the comparator CMP, the resistor R1, the resistor R2, and the reference voltage source VREF in the electronic circuit 500A.

The first electrode terminal 111A is connected to the first wiring 501 of the electronic circuit 500A. The second electrode terminal 112A is connected to the second wiring 502 of the electronic circuit 500A. The third electrode terminal 113A is connected to the third wiring 503 of the electronic circuit 500A.

The semiconductor module 100C shown in FIG. 8A shows a structure in which the semiconductor device 3 and the analog control chip 2B are separated on the conductive substrate 110. However, the semiconductor device 3 and the analog control chip 2B may be integrated into one chip, and the chip may be mounted on the conductive substrate 110.

Alternatively, as in the semiconductor module 100D shown in FIG. 8B, the second electrode terminal 112A and the third electrode terminal 113A may be placed on the opposite side of the first electrode terminal 111A.

Alternatively, as in the semiconductor module 100E shown in FIG. 8C, the third switching element FET3 may be placed between the first switching element FET1 and the second switching element FET2. This makes shorter the gate wiring between the third switching element FET3 and the first switching element FET1 and the gate wiring between the third switching element FET3 and the second switching element FET2. Thus, the resistance of each gate wiring is reduced.

According to the second embodiment, the first switching element FET1, the second switching element FET2, and the third switching element FET3 are integrated in the semiconductor device 3. In such structure, the first switching element FET1 and the second switching element FET2 can be connected to the third switching element FET3 not by a bonding wire but by an internal wiring routed in the semiconductor device 3. Thus, the number of bonding wires can be decreased. Furthermore, the gate wiring resistance of the first switching element FET1 and the second switching element FET2 is reduced.

In the semiconductor module 100C, 100D, the unit for handling large power can be separated from the unit for analog control. This enables design optimization for each unit.

The third switching element FET3 needs a mixed mounting process for power devices, and occupies a relatively large element area. In the second embodiment, the third switching element FET3 can be removed from the analog control chip. Then, the power consumption of the control part can be reduced by the fine CMOS process in the analog control chip in which the third switching element FET3 is not formed.

For instance, the second switching element FET2 may require a gate breakdown voltage of +20 V. In this case, the drain-source breakdown voltage of the third switching element FET3 needs to be higher than or equal to the absolute value of −20 V. Thus, the third switching element FET3 is difficult to form by the fine CMOS process used in forming the analog control chip. Accordingly, the third switching element FET3 is preferably formed in the chip provided with the first switching element FET1 and the second switching element FET2.

The semiconductor module 100C, 100D is provided with a MOSFET of the three-terminal structure including a source terminal, a drain terminal, and a gate terminal. This MOSFET is compatible with the conventional MOSFET of the three-terminal structure.

### Third Embodiment

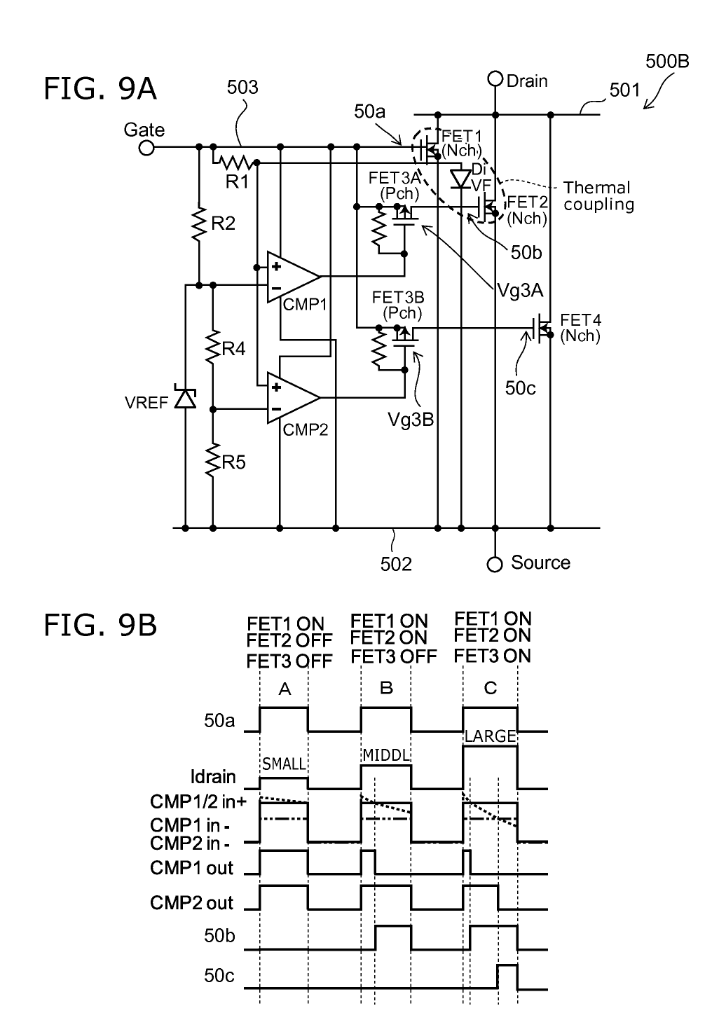

FIG. 9A is an electronic circuit diagram according to a third embodiment. FIG. 9B is a timing chart of the electronic circuit according to the third embodiment.

In the electronic circuit, the switching elements operated in parallel between the first wiring 501 and the second wiring 502 are not limited to the two switching elements, i.e., the first switching element FET1 and the second switching element FET2. According to the third embodiment, the number of switching elements operated in parallel between the first wiring 501 and the second wiring 502 can be set to at least three.

The electronic circuit 500B according to the third embodiment includes a fourth switching element FET4 besides the first switching element FET1 and the second switching element FET2 as the switching elements operated in parallel between the first wiring 501 and the second wiring 502.

For instance, in the electronic circuit 500B, the third switching element FET3 incorporated in the electronic circuit 500A is replaced by a third switching element FET3A having the same configuration as the third switching element FET3. Here, the reference numeral of the gate electrode of the third switching element FET3A is denoted as “Vg3A”. Furthermore, the electronic circuit 500B includes a fifth switching element FET3B.

In the electronic circuit 500B, the comparator CMP incorporated in the electronic circuit 500A is replaced by a comparator CMP1 having the same configuration as the comparator CMP. Furthermore, the electronic circuit 500B includes a comparator CMP2.

In the electronic circuit 500B, the rectification element Di is thermally coupled to the first switching element FET1 and the second switching element FET2. The rectification element Di changes its forward voltage (Vf) due to heat generated by at least one of the first switching element FET1 and the second switching element FET2.

The switching operation of the fourth switching element FET4 is controlled by its gate electrode 50c. The fourth switching element FET4 is e.g. an n-channel MOSFET. The fourth switching element FET4 is connected in parallel with the first switching element FET1 and the second switching element FET2 between the first wiring 501 and the second wiring 502.

The fifth switching element FET3B is connected between the third wiring 503 and the gate electrode 50c of the fourth switching element FET4. The fifth switching element FET3B includes a gate electrode Vg3B. The fifth switching element FET3B is e.g. a p-channel MOSFET.

When the fifth switching element FET3B is turned on, the gate electrode 50c of the fourth switching element FET4 is made electrically connected to the third wiring 503. When the gate electrode 50c is made electrically connected to the third wiring 503, the gate electrode 50c is supplied with a gate potential higher than or equal to the threshold voltage. This turns on the fourth switching element FET4. That is, the path between the first wiring 501 and the second wiring 502 is made electrically continuous also through the fourth switching element FET4.

The comparator CMP2 senses the potential difference between the anode voltage of the rectification element Di and a reference voltage. The potential of the gate electrode Vg3B of the fifth switching element FET3B changes depending on whether or not this potential difference is larger than or equal to a prescribed value. Accordingly, the fifth switching element FET3B is turned on or off. Here, the differences between the reference voltage and Vf compared by each of the comparator CMP1 and the comparator CMP2 are different. A resistor R4 is connected between the comparator CMP1 and the comparator CMP2. A resistor R5 is connected between the comparator CMP2 and the second wiring 502.

The operation of the electronic circuit 500B is described in more detail with reference to FIGS. 9A and 9B.

The gate electrode 50a of the first switching element FET1 is applied with a voltage higher than or equal to the threshold voltage (Vth). Then, the first switching element FET1 is turned on. Thus, a drain current flows between the source and the drain of the first switching element FET1. Here, the second switching element FET2, the third switching element FET3A, the fourth switching element FET4, and the fifth switching element FET3B are in the off-state. In FIG. 9B, the period of this state is shown as period A.

At this stage, the load on the first switching element FET1 is light, and the drain current is relatively small. In this case, the second switching element FET2, the third switching element FET3A, the fourth switching element FET4, and the fifth switching element FET3B are in the off-state, and only the first switching element FET1 is operated.

Next, when the load on the first switching element FET1 becomes heavier and increases the drain current, the first switching element FET1 generates heat by the conduction loss due to the on-resistance of the first switching element FET1. In FIG. 9B, the period of this state is shown as period B.

The element temperature of the first switching element FET1 increases with the increase in the drain current of the first switching element FET1. Then, the temperature of the rectification element Di increases, and Vf decreases. This Vf is compared with the reference voltage source VREF by the comparator CMP1. If the voltage is lower than the reference voltage source VREF, signal output from the comparator CMP1 to the gate electrode Vg3A of the third switching element FET3A is stopped. This turns on the third switching element FET3A. Thus, the gate electrode 50b of the second switching element FET2 is supplied with a potential higher than or equal to the threshold. This turns on the second switching element FET2. That is, the path between the first wiring 501 and the second wiring 502 is made electrically continuous also through the second switching element FET2.

Next, when the load on the first switching element FET1 and the second switching element FET2 becomes heavier and further increases the drain current, both the first switching element FET1 and the second switching element FET2 generate heat by the conduction loss due to the on-resistance of the first switching element FET1 and the on-resistance of the second switching element FET2. In FIG. 9B, the period of this state is shown as period C.

The element temperature of the first switching element FET1 and the second switching element FET2 increases with the increase in the drain current of the first switching element FET1 and the second switching element FET2. Then, the temperature of the rectification element Di further increases, and Vf further decreases. This Vf is compared with the reference voltage source VREF by the comparator CMP2. If the voltage is lower than the reference voltage source VREF, signal output from the comparator CMP2 to the gate electrode Vg3B of the fifth switching element FET3B is stopped. This turns on the fifth switching element FET3B.

Thus, the gate electrode 50c of the fourth switching element FET4 is supplied with a potential higher than or equal to the threshold. This turns on the fourth switching element FET4. That is, the path between the first wiring 501 and the second wiring 502 is made electrically continuous also through the fourth switching element FET4.

Thus, parallel operation in the order of the first switching element FET1, the second switching element FET2, and the fourth switching element FET4 is performed as heat generation in the electronic circuit 500B becomes higher. The element area of the switching elements is preferably designed as first switching element FET1 second switching element FET2 fourth switching element FET4.

### Fourth Embodiment

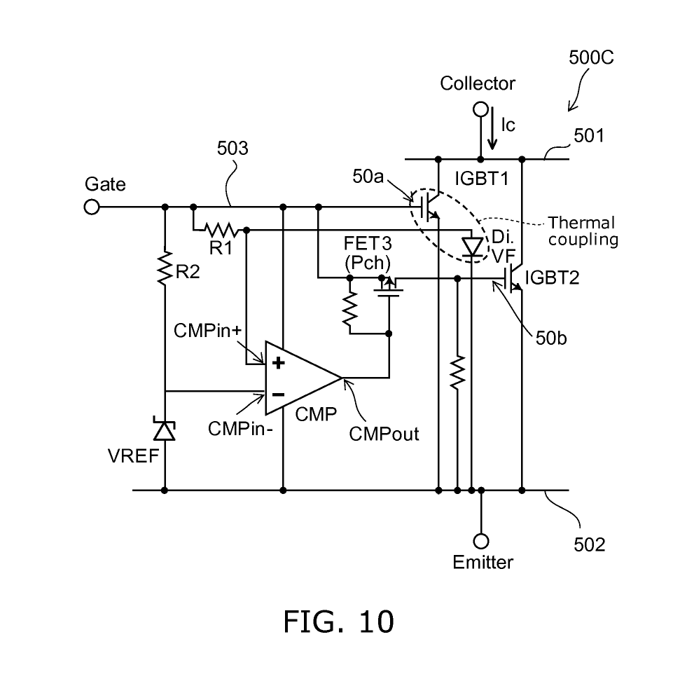

FIG. 10 is an electronic circuit diagram according to a fourth embodiment.

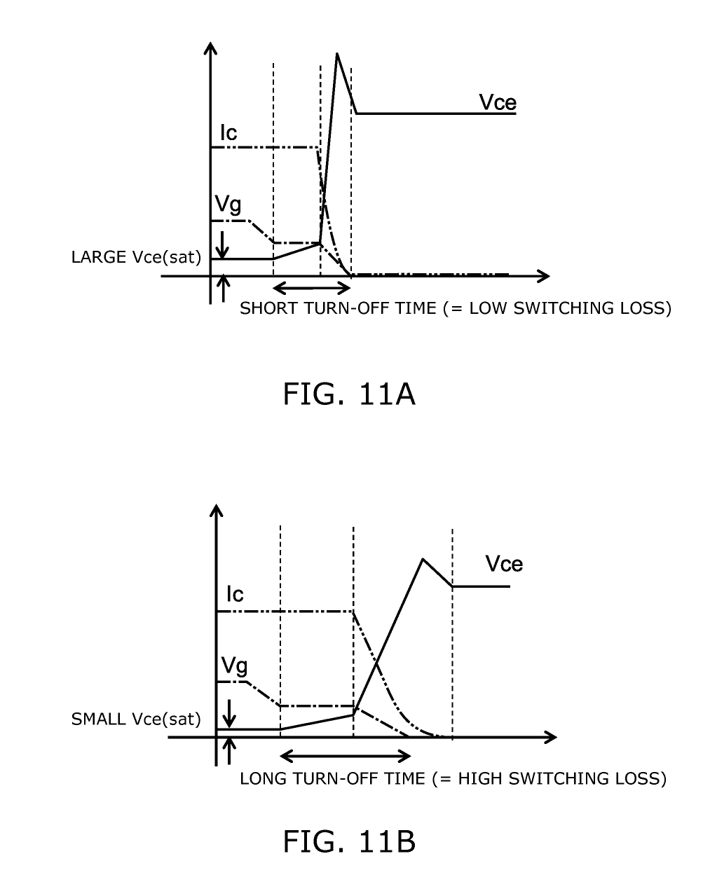

FIGS. 11A and 11B are timing charts of the electronic circuit according to the fourth embodiment. In the electronic circuit 500C shown in FIG. 10, the first switching element FET1 of the electronic circuit 500A is replaced by a sixth switching element IGBT1, and the second switching element FET2 is replaced by a seventh switching element IGBT2. Each of the sixth switching element IGBT1 and the seventh switching element IGBT2 includes an IGBT (insulated gate bipolar transistor).

The switching operation of the sixth switching element IGBT1 is controlled by its gate electrode 50a. The switching operation of the seventh switching element IGBT2 is controlled by its gate electrode 50b. Here, the first wiring 501 is a collector wiring, and the second wiring 502 is an emitter wiring.

In FIGS. 11A and 11B, the horizontal axis represents time. The vertical axis collectively represents the collector current (Ic), the gate voltage (Vg), and the collector-emitter saturation voltage (Vce(sat)).

FIG. 11A shows the situation corresponding to “period A” shown in FIG. 1B. In this case, only the sixth switching element IGBT1 is turned on. The current for the on-state of only the sixth switching element IGBT1 flows between the first wiring 501 and the second wiring 502. In this case, hole injection is relatively low, and the flowing time of the tail current is short. Thus, the turn-off time is short, and the switching loss is low. Vce(sat) is larger than Vce(sat) of FIG. 11B described below.

On the other hand, FIG. 11B shows the situation corresponding to “period B” shown in FIG. 1B. In this case, both the sixth switching element IGBT1 and the seventh switching element IGBT2 are turned on. Thus, a current larger than that of FIG. 11A flows between the first wiring 501 and the second wiring 502. In this case, hole injection is higher than that of FIG. 11A, and the flowing time of the tail current is longer. Thus, Vce(sat) is smaller than that of FIG. 11A. Accordingly, the conduction loss is reduced. Thus, the switching loss is low in the period A, and the conduction loss is reduced in the period B.

That is, in the electronic circuit 500C, the trade-off between Vce(sat) and turn-off loss is effectively eliminated.

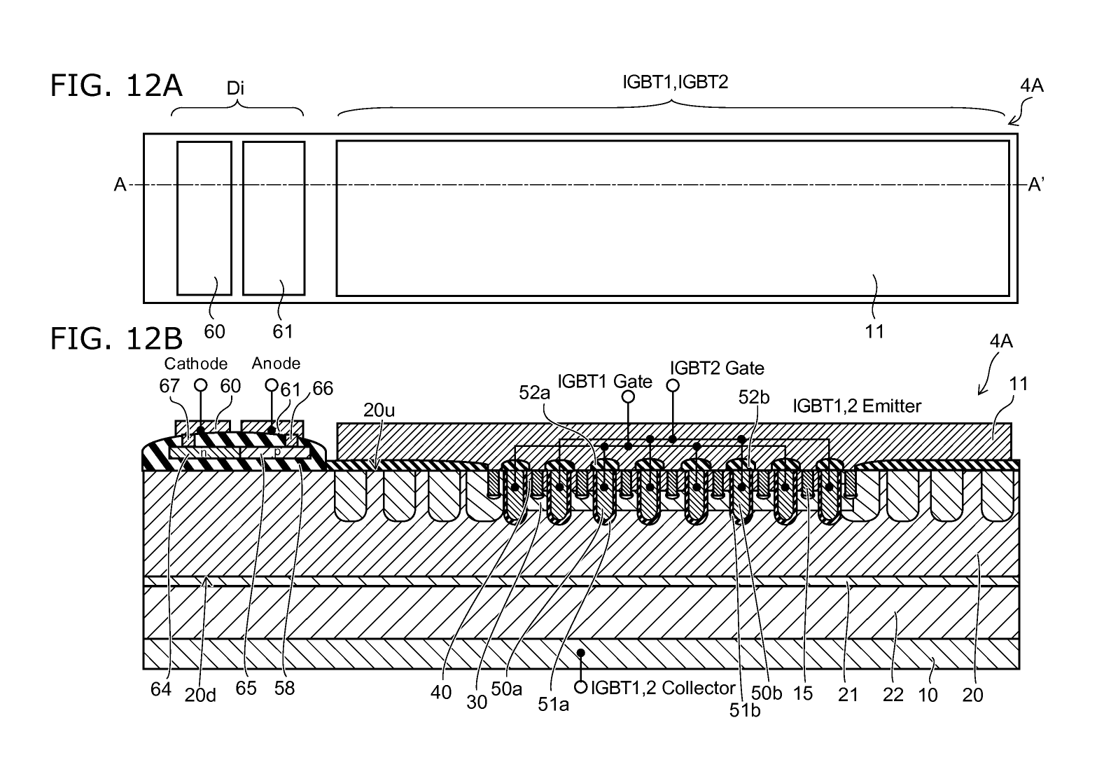

FIG. 12A is a schematic plan view of a first example of a semiconductor device according to the fourth embodiment. FIG. 12B is a schematic sectional view of the first example of the semiconductor device according to the fourth embodiment.

Here, FIG. 12B shows a cross section taken along line A-A′ of FIG. 12A.

The semiconductor device 4A shown in FIGS. 12A and 12B is a composite semiconductor device including the sixth switching element IGBT1, the seventh switching element IGBT2, and the rectification element Di. The semiconductor device 4A includes IGBTs of the trench gate structure.

In the semiconductor device 4A, an emitter electrode 11 is provided on a collector electrode 10. An n-type semiconductor layer 20 is provided between the collector electrode 10 and the emitter electrode 11. A p⁺-type collector layer 22 is provided between the semiconductor layer 20 and the collector electrode 10. The impurity concentration of the collector layer 22 is higher than the impurity concentration of the base region 30. An n-type buffer layer 21 is provided between the collector layer 22 and the semiconductor layer 20. The impurity concentration of the buffer layer 21 is higher than the impurity concentration of the semiconductor layer 20.

In the semiconductor device 4A, the base region 30 of p-type is provided between the semiconductor layer 20 and the emitter electrode 11. An emitter region 40 is provided between the base region 30 and the emitter electrode 11. The emitter region 40 is in contact with the emitter electrode 11. The conductivity type of the emitter region 40 is n⁺-type. The impurity concentration of the emitter region 40 is higher than the impurity concentration of the semiconductor layer 20.

The gate electrode 50a is in contact with the semiconductor layer 20, the base region 30, and the emitter region 40 via a gate insulating film 51a. The semiconductor device 4A includes a plurality of gate electrodes 50a.

The sixth switching element IGBT1 includes the emitter electrode 11, the collector electrode 10, the semiconductor layer 20, the base region 30, the emitter region 40, the buffer layer 21, the collector layer 22, the gate electrode 50a and the like.

In the semiconductor device 4A, a gate electrode 50b is provided besides the gate electrode 50a. The gate electrode 50b is in contact with the semiconductor layer 20, the base region 30, and the emitter region 40b via a gate insulating film 51b. The semiconductor device 4A includes a plurality of gate electrodes 50b.

In the semiconductor device 4A, the gate electrodes 50a and the gate electrodes 50b are arranged alternately in a direction crossing (e.g., perpendicular to) the direction from the collector electrode 10 toward the emitter electrode 11. For instance, the gate electrodes 50a and the gate electrodes 50b are arranged alternately in a direction parallel to the upper surface 20u of the semiconductor layer 20. The seventh switching element IGBT2 includes the emitter electrode 11, the collector electrode 10, the semiconductor layer 20, the base region 30, the emitter region 40, the buffer layer 21, the collector layer 22, the gate electrode 50b and the like.

The sixth switching element IGBT1 and the seventh switching element IGBT2 share the semiconductor layer 20, the base region 30, and the emitter region 40. Each of the sixth switching element IGBT1 and the seventh switching element IGBT2 includes a separate gate electrode, and are independently controlled by the respective gate electrodes.

In the semiconductor device 4A, the rectification element Di includes an n-type semiconductor region 64, a p-type semiconductor region 65, a cathode electrode 60, and an anode electrode 61. The rectification element Di of the semiconductor device 4A is thermally coupled to the sixth switching element IGBT1 or the seventh switching element IGBT2.

The n-type semiconductor region 64 and the p-type semiconductor region 65 are provided above the upper surface 20u of the semiconductor layer 20. The cathode electrode 60 is connected to the n-type semiconductor region 64 through a contact 67. The anode electrode 61 is connected to the p-type semiconductor region 65 through a contact 66. The n-type semiconductor region 64 and the p-type semiconductor region 65 are surrounded with an insulating layer 58 provided on the upper surface 20u of the semiconductor layer 20. The rectification element Di may be the rectification element Di shown in FIG. 2B.

The gate electrodes 50a and the gate electrodes 50b are alternately arranged in the semiconductor device 4A. Thus, the semiconductor device 4A is operated as described below.

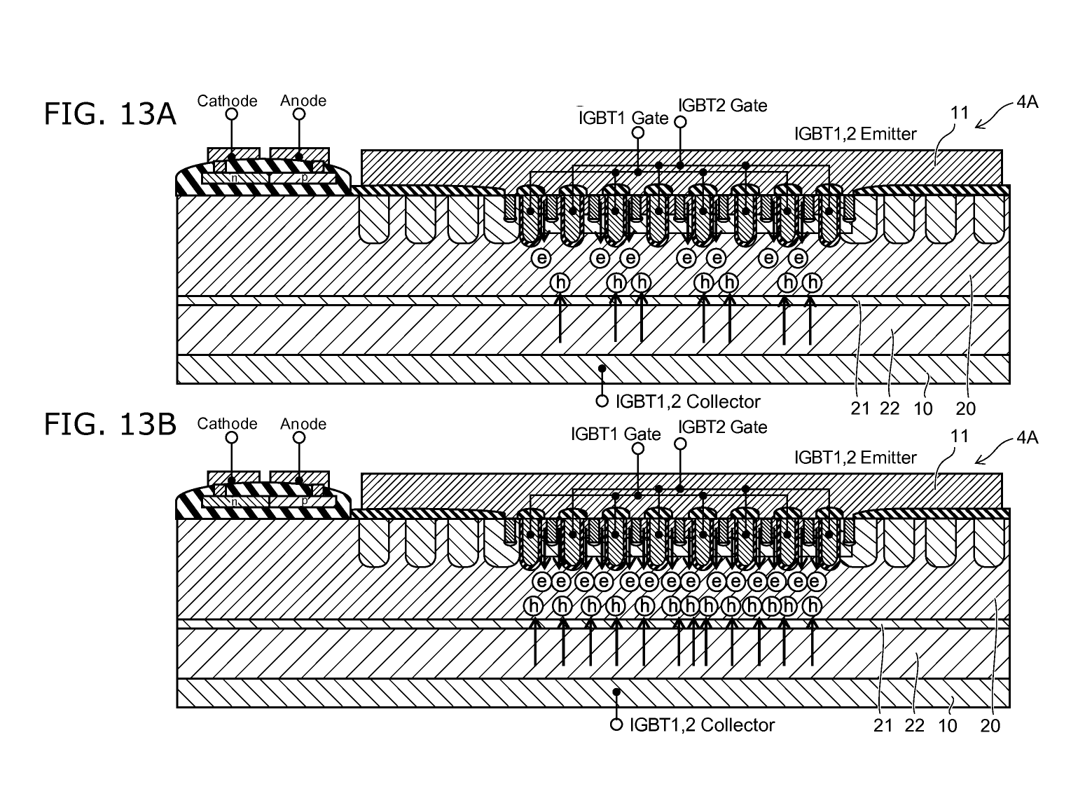

FIGS. 13A and 13B are schematic sectional views showing the operation of the first example of the semiconductor device according to the fourth embodiment. In the figures, the symbol “e” represents an electron, and the symbol “h” represents a hole, schematically. The arrow in the figures schematically represents formation of a channel.

In the state shown in FIG. 13A, among a plurality of gate electrodes, only the gate electrodes 50a are applied with a voltage higher than or equal to the threshold. In other words, the gate electrodes 50a approximately as many as half the plurality of gate electrodes are applied with a voltage higher than or equal to the threshold. That is, in the state shown in FIG. 13A, the number of electrons injected by the gates is limited, and the number of holes injected into the element is also small. Thus, carriers are rapidly annihilated at turn-off time. Accordingly, the switching operation is fast.

On the other hand, in the state shown in FIG. 13B, the gate electrodes 50a and the gate electrodes 50b are applied with a voltage higher than or equal to the threshold. That is, all the plurality of gate electrodes are applied with a voltage higher than or equal to the threshold. Thus, in the state shown in FIG. 13B, the number of injected carriers is larger than in the state shown in FIG. 13A. That is, the state shown in FIG. 13B is more heavily loaded than the state shown in FIG. 13A. Thus, the collector-emitter saturation voltage (Vce(sat)) is reduced at turn-off time. Accordingly, the conduction loss is reduced.

Furthermore, by the alternate arrangement of the gate electrodes 50a and the gate electrodes 50b, the number of carriers per unit area in the semiconductor layer 20 under operation is smaller than that of the semiconductor device 4B described later. Thus, the turn-off time is shorter. When only the gate electrodes 50a are applied with a voltage higher than or equal to the threshold potential and only the sixth switching element IGBT1 is operated, the gate electrodes 50b are placed at e.g. 0 V. Thus, holes are easily accumulated in the semiconductor layer 20 below the gate electrode 50b, and conduction modulation is more likely to occur. Accordingly, the semiconductor device 4A has a lower on-resistance than the semiconductor device 4B.

The embodiment also encompasses the structure in which the collector layer 22 is removed from the semiconductor device 4A. That is, the embodiment also encompasses the structure of a MOSFET in which the gate electrodes 50a and the gate electrodes 50b are arranged alternately in a direction parallel to the upper surface 20u of the semiconductor layer 20.

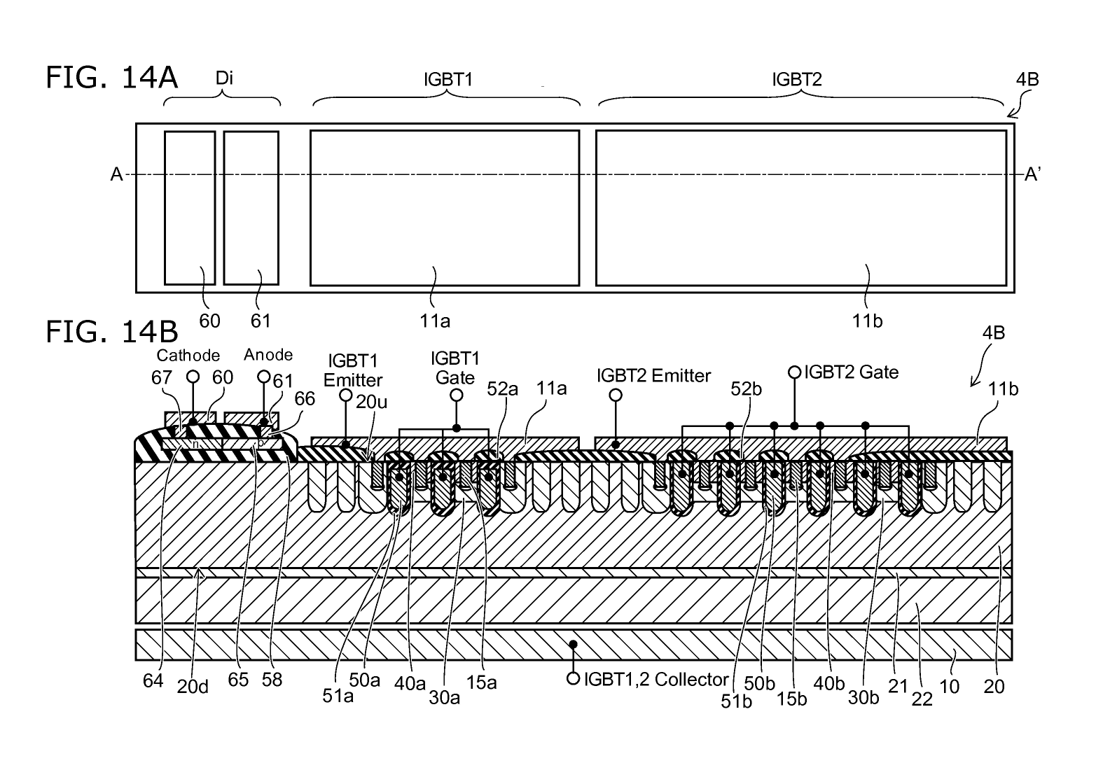

FIG. 14A is a schematic plan view of a second example of the semiconductor device according to the fourth embodiment. FIG. 14B is a schematic sectional view of the second example of the semiconductor device according to the fourth embodiment.

In the semiconductor device 4B, the emitter electrode 11 includes a first electrode part 11a and a second electrode part 11b. The base region 30 is divided into a base region 30a and a base region 30b. The rectification element Di is placed near the sixth switching element IGBT1 and thermally coupled to the sixth switching element IGBT1. The rectification element Di may be the rectification element Di shown in FIG. 2B.

The base region 30a is provided between the semiconductor layer 20 and the first electrode part 11a of the emitter electrode 11. The emitter region 40a is provided between the base region 30a and the first electrode part 11a of the emitter electrode 11. The emitter region 40a is in contact with the first electrode part 11a. The conductivity type of the emitter region 40a is n⁺-type. The impurity concentration of the emitter region 40a is higher than the impurity concentration of the semiconductor layer 20.

The gate electrode 50a is in contact with the semiconductor layer 20, the base region 30a, and the emitter region 40a via a gate insulating film 51a. An interlayer insulating film 52a is provided between the gate electrode 50a and the first electrode part 11a of the emitter electrode 11. The semiconductor device 4B includes a plurality of gate electrodes 50a.

The sixth switching element IGBT1 includes the first electrode part 11a of the emitter electrode 11, the collector electrode 10 below the first electrode part 11a, the semiconductor layer 20 between the first electrode part 11a and the collector electrode 10, the buffer layer 21, the collector layer 22, the base region 30a, the emitter region 40a, the gate electrode 50a and the like.

The base region 30b is provided in a region different from the region provided with the base region 30a. The base region 30b is provided between the semiconductor layer 20 and the second electrode part 11b of the emitter electrode 11. The conductivity type of the base region 30b is p-type.

The emitter region 40b is provided between the base region 30b and the second electrode part 11b of the emitter electrode 11. The emitter region 40b is in contact with the second electrode part 11b. The conductivity type of the emitter region 40b is n⁺-type. The impurity concentration of the emitter region 40b is higher than the impurity concentration of the semiconductor layer 20.

The gate electrode 50b is in contact with the semiconductor layer 20, the base region 30b, and the emitter region 40b via a gate insulating film 51b. An interlayer insulating film 52b is provided between the gate electrode 50b and the second electrode part 11b of the emitter electrode 11. The semiconductor device 4B includes a plurality of gate electrodes 50b.

The seventh switching element IGBT2 includes the second electrode part 11b of the emitter electrode 11, the collector electrode 10 below the second electrode part 11b, the semiconductor layer 20 between the second electrode part 11b and the collector electrode 10, the buffer layer 21, the collector layer 22, the base region 30b, the emitter region 40b, the gate electrode 50b and the like.

The sixth switching element IGBT1 and the seventh switching element IGBT2 share the semiconductor layer 20, the buffer layer 21, and the collector layer 22. Each of the sixth switching element IGBT1 and the seventh switching element IGBT2 each includes a separate gate electrode, and are independently controlled by the respective gate electrodes.

### Fifth Embodiment

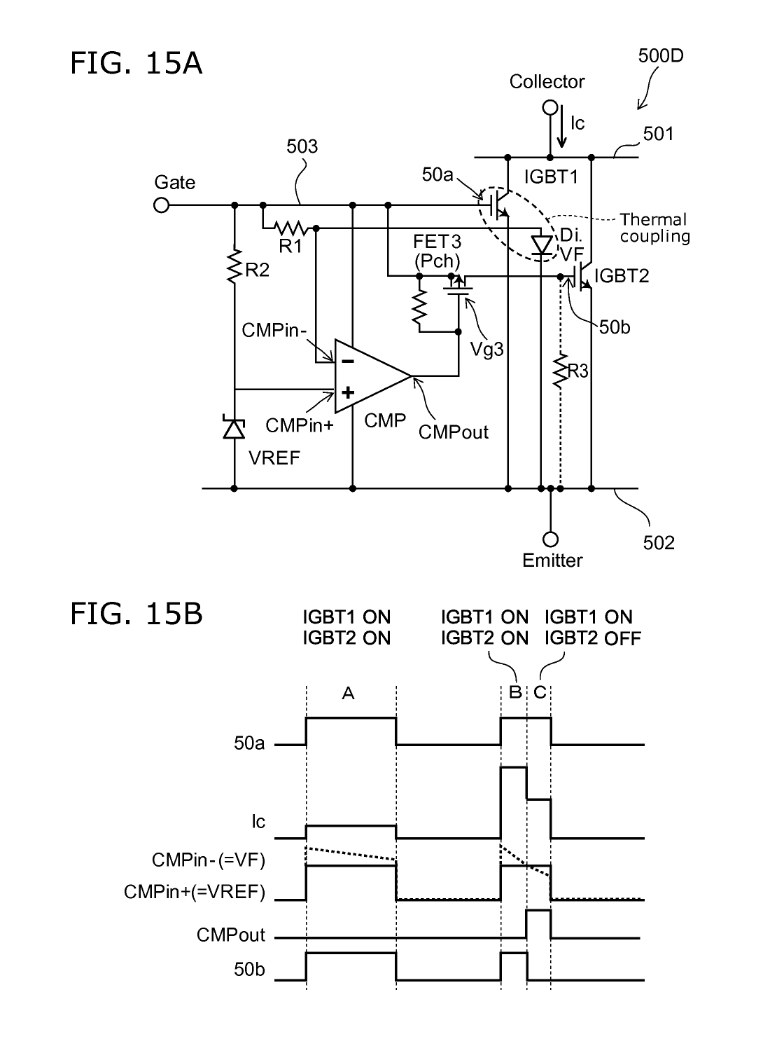

FIG. 15A is an electronic circuit diagram according to a fifth embodiment. FIG. 15B is a timing chart of the electronic circuit according to the fifth embodiment.

In the electronic circuit 500D shown in FIG. 15A, the rectification element Di is thermally coupled to the sixth switching element IGBT1 and the seventh switching element IGBT2. However, in the electronic circuit 500D, connection of the inverting input (in−) and the non-inverting input (in+) of the comparator CMP is opposite to that in the electronic circuit 500C.

By this opposite connection, the comparator CMP ceases to supply a voltage to the gate electrode Vg3 of the third switching element FET3 when the potential difference between the anode voltage of the rectification element Di and the reference voltage is larger than or equal to the prescribed value. As a result, the p-type third switching element FET3 is turned on.

When the third switching element FET3 is turned on, the gate electrode 50b of the seventh switching element IGBT2 is made electrically connected to the third wiring 503. When the gate electrode 50b is made electrically connected to the third wiring 503, the gate electrode 50b is supplied with a gate potential higher than or equal to the threshold voltage (Vth). This turns on the seventh switching element IGBT2.

That is, in the electronic circuit 500D, in advance, in the period A shown in FIG. 15B, the path between the first wiring 501 and the second wiring 502 is made electrically continuous through the sixth switching element IGBT1 and the seventh switching element IGBT2.

However, if the sixth switching element IGBT1 and the seventh switching element IGBT2 continue operation, and a large current continues to flow between the first wiring 501 and the second wiring 502, then the sixth switching element IGBT1 and the seventh switching element IGBT2 may be driven to the verge of load short circuit. This state is denoted as period B. Here, the third switching element FET3 includes a p-channel transistor. Thus, the comparator CMP supplies a voltage to the gate electrode Vg3 of the third switching element FET3 when the anode voltage is higher than or equal to the reference voltage. That is, the transistor of the third switching element FET3 is in the on-state. In this case, the amount of heat generated from the sixth switching element IGBT1 and the seventh switching element IGBT2 is even higher. If load short circuit occurs, the sixth switching element IGBT1 and the seventh switching element IGBT2 are thermally destroyed.

In the electronic circuit 500D, connection of the inverting input (in−) and the non-inverting input (in+) of the comparator CMP is opposite to that in the electronic circuit 500C. Thus, when the potential difference between the anode voltage of the rectification element Di and the reference voltage is smaller than the prescribed value, the comparator CMP outputs a voltage. This turns off the p-channel third switching element FET3. Thus, the potential of the gate electrode 50b of the seventh switching element IGBT2 is made lower than the threshold. That is, the seventh switching element IGBT2 is also turned off. In FIG. 15B, this state is denoted as period C.

When the anode voltage is lower than the reference voltage, the comparator CMP does not supply a voltage to the gate electrode Vg3 of the third switching element FET3. Thus, the transistor of the third switching element FET3 is in the off-state. Accordingly, in the period C, the path between the first wiring 501 and the second wiring 502 is electrically discontinuous through the seventh switching element IGBT2 and electrically continuous through the sixth switching element IGBT1.

Thus, in the electronic circuit 500D, the sixth switching element IGBT1 and the seventh switching element IGBT2 are both operated during normal operation. As soon as load short circuit occurs, or immediately before load short circuit, the seventh switching element IGBT2 is turned off to suppress the saturation current. This suppresses the thermal destruction of the semiconductor device.

### Sixth Embodiment

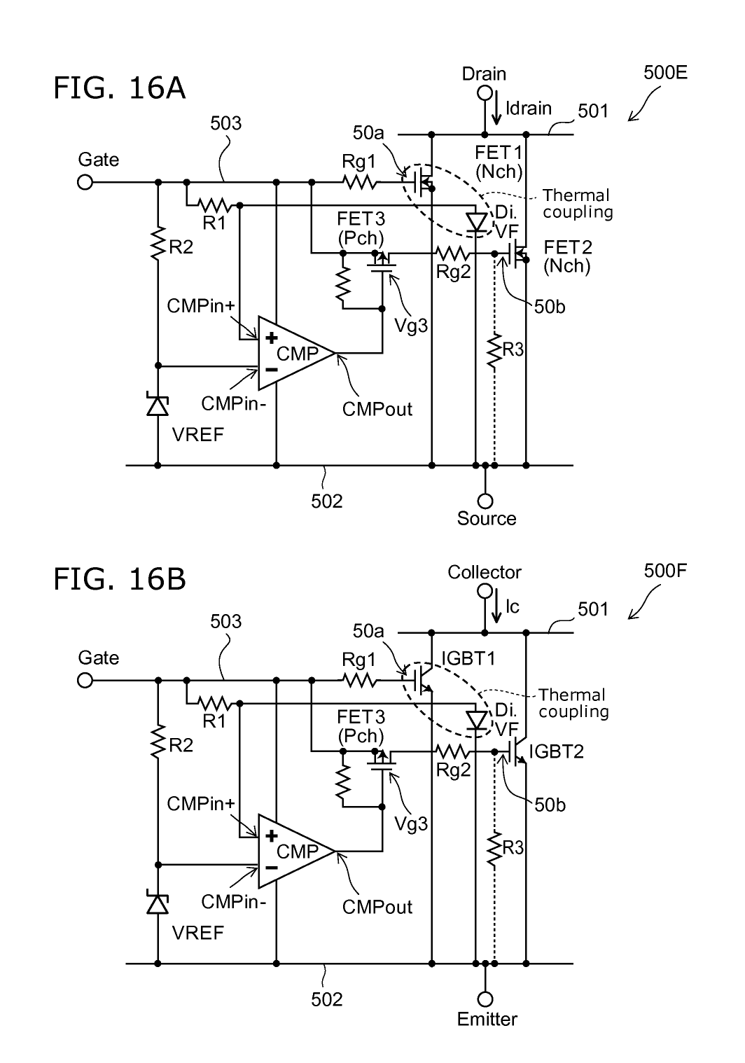

FIG. 16A is an electronic circuit diagram of a first example according to a sixth embodiment. FIG. 16B is an electronic circuit diagram of a second example according to the sixth embodiment.

In the electronic circuit 500E shown in FIG. 16A, in addition to the configuration of the electronic circuit 500A, a resistance element Rg1 is connected between the third wiring 503 and the gate electrode 50a of the first switching element FET1. Furthermore, in the electronic circuit 500E, in addition to the configuration of the electronic circuit 500A, a resistance element Rg2 is connected between the third switching element FET3 and the gate electrode 50b of the second switching element FET2.

For instance, the area occupied by the active region of the first switching element FET1 may be smaller than the area occupied by the active region of the second switching element FET2. Then, the resistances are set as resistance(Rg1)<resistance(Rg2).

Thus, when the first switching element FET1 is operated, the resistance of the resistance element Rg1 is low. This realizes fast operation of the first switching element FET1. On the other hand, when the second switching element FET2 is operated, the resistance of the resistance element Rg2 is high. This can prevent unnecessary current from flowing into the gate electrode 50b of the second switching element FET2. Furthermore, gate oscillation is suppressed.

In the electronic circuit 500F shown in FIG. 16B, in addition to the configuration of the electronic circuit 500C, a resistance element Rg1 is connected between the third wiring 503 and the gate electrode 50a of the sixth switching element IGBT1. Furthermore, in the electronic circuit 500F, in addition to the configuration of the electronic circuit 500C, a resistance element Rg2 is connected between the third switching element FET3 and the gate electrode 50b of the seventh switching element IGBT2.

For instance, the area occupied by the active region of the sixth switching element IGBT1 may be smaller than the area occupied by the active region of the seventh switching element IGBT2. Then, the resistances are set as resistance (Rg1)<resistance (Rg2).

Thus, when the sixth switching element IGBT1 is operated, the resistance of the resistance element Rg1 is low. This realizes fast operation of the sixth switching element IGBT1. On the other hand, when the seventh switching element IGBT2 is operated, the resistance of the resistance element Rg2 is high. This can prevent unnecessary current from flowing into the gate electrode 50b of the seventh switching element IGBT2. Furthermore, gate oscillation is suppressed.

### Seventh Embodiment

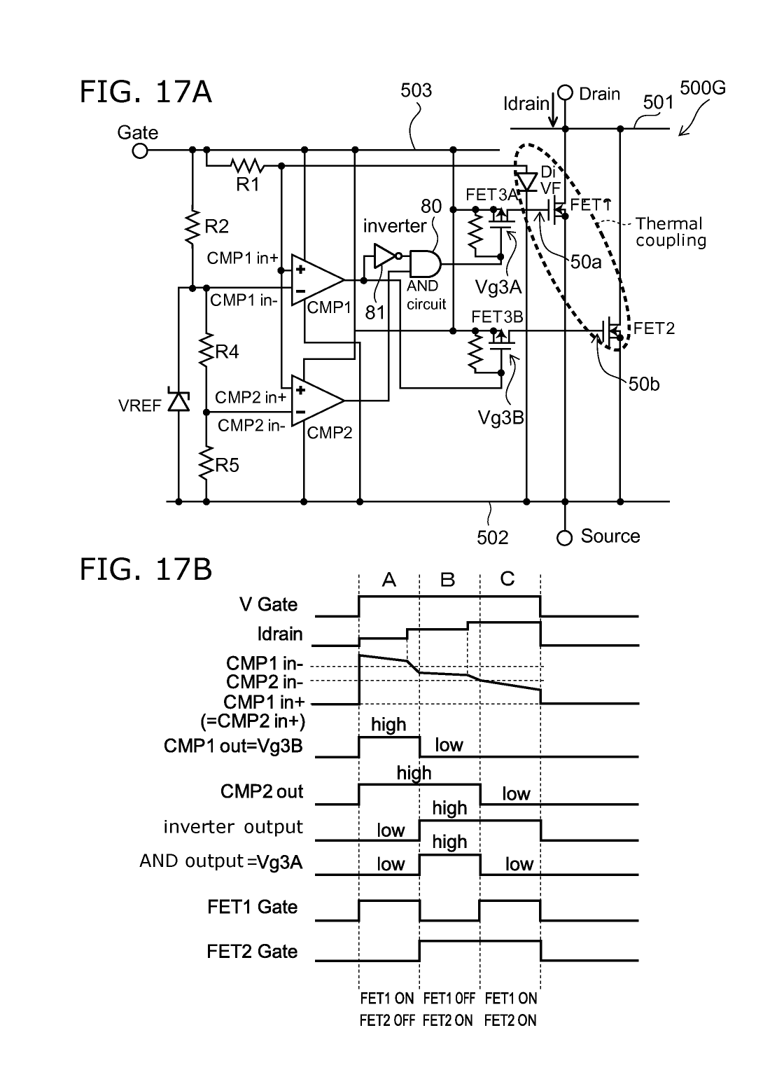

FIG. 17A is an electronic circuit diagram according to a seventh embodiment. FIG. 17B is a timing chart of the electronic circuit according to the seventh embodiment.

The electronic circuit 500G shown in FIG. 17A includes a first wiring 501, a second wiring 502, a third wiring 503, a first switching element FET1, a second switching element FET2, a rectification element Di, a third switching element FET3A, a fifth switching element FET3B, an AND circuit element 80, an inverter circuit element 81, and comparators CMP1, CMP2.

Here, it is assumed that the active area of the first switching element FET1 is smaller than the active area of the second switching element FET2.

The first switching element FET1 is connected between the first wiring 501 and the second wiring 502. Its gate electrode 50a is connected to the source of the third switching element FET3A. The second switching element FET2 is connected in parallel with the first switching element FET1 between the first wiring 501 and the second wiring 502. Its gate electrode 50b is connected to the source of the fifth switching element FET3B.

The third switching element FET3A is connected between the third wiring 503 and the gate electrode 50a of the first switching element FET1. The fifth switching element FET3B is connected between the third wiring 503 and the gate electrode 50b of the second switching element FET2.

When the third switching element FET3A is turned on, the gate electrode 50a of the first switching element FET1 is made electrically connected to the third wiring 503. When the gate electrode 50a is made electrically connected to the third wiring 503, the gate electrode 50a is supplied with a gate potential higher than or equal to the threshold voltage. This turns on the first switching element FET1. That is, the path between the first wiring 501 and the second wiring 502 is made electrically continuous through the first switching element FET1.

When the fifth switching element FET3B is turned on, the gate electrode 50b of the second switching element FET2 is made electrically connected to the third wiring 503. When the gate electrode 50b is made electrically connected to the third wiring 503, the gate electrode 50b is supplied with a gate potential higher than or equal to the threshold voltage. This turns on the second switching element FET2. That is, the path between the first wiring 501 and the second wiring 502 is made electrically continuous through the second switching element FET2.

The rectification element Di is e.g. a p-n diode including an anode electrode and a cathode electrode. The anode electrode of the rectification element Di is connected to the third wiring 503 through a resistor R1. The cathode electrode is connected to the second wiring 502. This rectification element Di is thermally coupled to the first switching element FET1 and the second switching element FET2.

The output side of the comparator CMP1 is connected to both the gate electrode Vg3A of the third switching element FET3A and the gate electrode Vg3B of the fifth switching element FET3B. However, the AND circuit element 80 is connected between the comparator CMP1 and the gate electrode Vg3A of the third switching element FET3A. Furthermore, the inverter circuit element 81 is connected between the comparator CMP1 and the AND circuit element 80.

The comparator CMP2 is connected to the gate electrode Vg3A of the third switching element FET3A. However, the AND circuit element 80 is connected between the comparator CMP2 and the gate electrode Vg3A of the third switching element FET3A.

The operation of the electronic circuit 500G is now described with reference to the timing chart of FIG. 17B.

First, the period A is described.

When the first switching element FET1 is in the on-state and the second switching element FET2 is in the off-state, Vf of the rectification element Di is relatively high. This state is referred to as light load state.

Here, the comparator CMP1 receives the voltage VR1 from the reference voltage source VREF as an inverting input (in−), and the anode voltage of the rectification element Di as a non-inverting input (in+).

If the difference between the voltage VR1 and the anode voltage of the rectification element Di is larger than a prescribed value, a voltage is outputted from the comparator CMP1 and applied to the gate electrode Vg3B of the fifth switching element FET3B. In this case, even if the gate electrode Vg3B is supplied with the voltage, the fifth switching element FET3B maintains its off-state because it is a p-channel MOSFET.

Furthermore, the comparator CMP2 receives the voltage VR2 from the reference voltage source VREF dropped by the resistor R4 as an inverting input (in−), and the anode voltage of the rectification element Di as a non-inverting input (in+).

If the difference between the voltage VR2 and the anode voltage of the rectification element Di is larger than a prescribed value, a voltage is outputted from the comparator CMP2, and the voltage signal is outputted to the AND circuit element 80.

Here, the AND circuit element 80 receives as inputs the signal outputted from the comparator CMP1 and inverted by the inverter circuit element 81 (i.e., Low signal), and the High signal outputted from the comparator CMP2. Thus, the AND circuit element 80 supplies a Low signal to the gate electrode Vg3A of the third switching element FET3A. That is, the p-channel third switching element FET3A maintains its on-state. Thus, the gate electrode 50a of the first switching element FET1 is supplied with a voltage higher than or equal to the threshold voltage from the third wiring 503. That is, the first switching element FET1 maintains its on-state. This makes the path between the first wiring 501 and the second wiring 502 electrically continuous through the first switching element FET1.

Next, the period B is described.

The current continues to flow in the first switching element FET1 and increases the element temperature of the first switching element FET1. Then, the temperature of the rectification element Di increases. Thus, the anode voltage of the rectification element Di decreases. Subsequently, the anode voltage of the rectification element Di continues to decrease. When the difference between the voltage VR1 and the anode voltage of the rectification element Di becomes smaller than the prescribed value, the comparator CMP1 ceases to produce the output.

Thus, voltage supply to the gate electrode Vg3B of the fifth switching element FET3B is stopped. This turns on the fifth switching element FET3B. Thus, the gate electrode 50b of the second switching element FET2 is supplied with a potential higher than or equal to the threshold from the third wiring 503. This turns on the second switching element FET2. That is, the path between the first wiring 501 and the second wiring 502 is made electrically continuous through the second switching element FET2.

Here, the difference between the voltage VR2 and the anode voltage of the rectification element Di is larger than or equal to the prescribed value. Thus, the comparator CMP2 outputs a High signal.

At this time, the AND circuit element 80 receives as inputs the signal outputted from the comparator CMP1 and inverted by the inverter circuit element 81 (i.e., High signal), and the High signal outputted from the comparator CMP2. Thus, the AND circuit element 80 supplies a High signal to the gate electrode Vg3A of the third switching element FET3A. Thus, the p-channel third switching element FET3A is turned off. That is, the first switching element FET1 maintains its off-state, and the second switching element FET2 maintains its on-state. This makes the path between the first wiring 501 and the second wiring 502 electrically continuous through the second switching element FET2.

In this state, the path between the first wiring 501 and the second wiring 502 is made electrically continuous through the second switching element FET2 having a larger active area than the first switching element FET1. This state is referred to as medium load state.

Next, the period C is described.

The current continues to flow in the second switching element FET2 and increases the element temperature of the second switching element FET2. Then, the temperature of the rectification element Di further increases. Thus, the anode voltage of the rectification element Di further decreases. Subsequently, the anode voltage of the rectification element Di continues to decrease. When both the difference between the voltage VR1 and the anode voltage of the rectification element Di and the difference between the voltage VR2 and the anode voltage of the rectification element Di become smaller than the prescribed value, both the comparators CMP1, CMP2 cease to produce the output.

Thus, voltage supply to the gate electrode Vg3B of the fifth switching element FET3B is stopped. This turns on the fifth switching element FET3B. Thus, the gate electrode 50b of the second switching element FET2 is supplied with a potential higher than or equal to the threshold from the third wiring 503. This turns on the second switching element FET2. That is, the path between the first wiring 501 and the second wiring 502 is made electrically continuous through the second switching element FET2.

Here, the difference between the voltage VR2 and the anode voltage of the rectification element Di is smaller than the prescribed value. Thus, the comparator CMP2 outputs a Low signal.

At this time, the AND circuit element 80 receives as inputs the signal outputted from the comparator CMP1 and inverted by the inverter circuit element 81 (i.e., High signal), and the Low signal outputted from the comparator CMP2. Thus, the AND circuit element 80 supplies a Low signal to the gate electrode Vg3A of the third switching element FET3A. Thus, the p-channel third switching element FET3A is turned on. That is, the first switching element FET1 maintains its on-state, and the second switching element FET2 maintains its on-state. This makes the path between the first wiring 501 and the second wiring 502 electrically continuous through the first switching element FET1 and the second switching element FET2. This state is referred to as heavy load state.

In the periods A-C, the gate potential of any of the first switching element FET1 and the second switching element FET2 is higher than or equal to the threshold.

Thus, switching can be performed in three stages among only the first switching element FET1 being turned on, only the second switching element FET2 being turned on, and the first switching element FET1 and the second switching element FET2 being turned on. This can improve the trade-off between capacitance and on-resistance in a wider current range.

### Eighth Embodiment

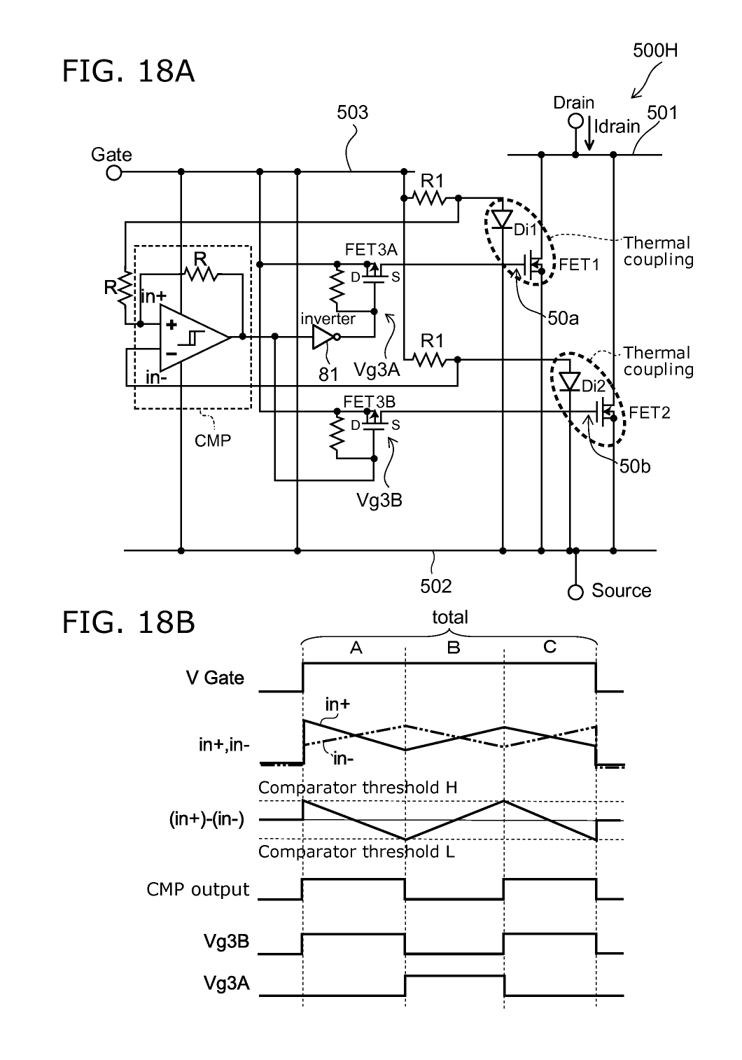

FIG. 18A is an electronic circuit diagram according to an eighth embodiment. FIG. 18B is a timing chart of the electronic circuit according to the eighth embodiment.

The electronic circuit 500H shown in FIG. 18A includes a first wiring 501, a second wiring 502, a third wiring 503, a first switching element FET1, a second switching element FET2, a rectification element Di1 and a rectification element Dig having the same configuration and function as the rectification element Di, a third switching element FET3A, a fifth switching element FET3B, an inverter circuit element 81, and a comparator CMP.

The first switching element FET1 is connected between the first wiring 501 and the second wiring 502. Its gate electrode 50a is connected to the source of the third switching element FET3A. The second switching element FET2 is connected in parallel with the first switching element FET1 between the first wiring 501 and the second wiring 502. Its gate electrode 50b is connected to the source of the fifth switching element FET3B.

The third switching element FET3A is connected between the third wiring 503 and the gate electrode 50a of the first switching element FET1. The fifth switching element FET3B is connected between the third wiring 503 and the gate electrode 50b of the second switching element FET2.

When the third switching element FET3A is turned on, the gate electrode 50a of the first switching element FET1 is made electrically connected to the third wiring 503. When the gate electrode 50a is made electrically connected to the third wiring 503, the gate electrode 50a is supplied with a gate potential higher than or equal to the threshold voltage. This turns on the first switching element FET1. That is, the path between the first wiring 501 and the second wiring 502 is made electrically continuous through the first switching element FET1.

When the fifth switching element FET3B is turned on, the gate electrode 50b of the second switching element FET2 is made electrically connected to the third wiring 503. When the gate electrode 50b is made electrically connected to the third wiring 503, the gate electrode 50b is supplied with a gate potential higher than or equal to the threshold voltage. This turns on the second switching element FET2. That is, the path between the first wiring 501 and the second wiring 502 is made electrically continuous through the second switching element FET2.

The anode electrode of the rectification element Di1 is connected to the third wiring 503 through a resistor R1. The cathode electrode is connected to the second wiring 502. Here, the rectification element Di1 is thermally coupled to the first switching element FET1.

The anode electrode of the rectification element Di2 is connected to the third wiring 503 through a resistor R1. The cathode electrode is connected to the second wiring 502. Here, the rectification element Di2 is thermally coupled to the second switching element FET2.

The comparator CMP is e.g. a Schmitt triggered comparator. The output side of the comparator CMP is connected to both the gate electrode Vg3A of the third switching element FET3A and the gate electrode Vg3B of the fifth switching element FET3B. However, the inverter circuit element 81 is connected between the comparator CMP and the gate electrode Vg3A of the third switching element FET3A.

The comparator CMP is subjected to positive feedback by a resistor R. In the comparator CMP, when the value of (non-inverting input (in+)−inverting input (in−)) transitions from High to Low, the threshold of the comparator CMP falls from “H” to “L”. On the other hand, when the value of (non-inverting input (in+)−inverting input (in−)) transitions from Low to High, the threshold of the comparator CMP rises from “L” to “H”. By using such a comparator CMP, the first switching element FET1 and the second switching element FET2 can be stably switched. Here, the resistor R is provided between the non-inverting input (in+) and the resistor R1.

For instance, in the period A, the first switching element FET1 may be in the on-state, and the second switching element FET2 may be in the off-state. In this state, the current continues to flow in the first switching element FET1. Then, the temperature of the rectification element Di1 continues to increase. Thus, its anode voltage continues to decrease.

Here, the comparator CMP receives the anode voltage Vat of the rectification element Di2 as an inverting input (in−), and the anode voltage Va1 of the rectification element Di1 as a non-inverting input (in+). Here, (non-inverting input (in+)−inverting input (in−)) falls in the period A.

The difference (Va1−Va2) between the voltage Va1 and the voltage Va2 is larger than or equal to the threshold L. Thus, the comparator CMP outputs a voltage. However, the inverter circuit element 81 exists between the gate electrode Vg3A and the comparator CMP. Thus, the output signal from the comparator CMP is inverted. Accordingly, the gate electrode Vg3A is not applied with a voltage. Thus, the third switching element FET3A is turned on, and the gate electrode 50a of the first switching element FET1 is supplied with a voltage higher than or equal to the threshold voltage from the third wiring 503. That is, the first switching element FET1 is turned on. This makes the path between the first wiring 501 and the second wiring 502 electrically continuous through the first switching element FET1.

In the period A, the comparator CMP supplies a voltage to the gate electrode Vg3B of the fifth switching element FET3B. This turns off the fifth switching element FET3B. Thus, the gate electrode 50b of the second switching element FET2 is not supplied with a voltage higher than or equal to the threshold voltage from the third wiring 503. Accordingly, the second switching element FET2 maintains its off-state.

Here, before the period A, it is assumed that the second switching element FET2 is in the on-state, and the first switching element FET1 is in the off-state. In the period A, the second switching element FET2 is turned off. Thus, the temperature of the rectification element Di2 gradually decreases. Accordingly, Vf of the rectification element Di2 gradually increases in the period A.

Then, in the period B, the difference between the voltage Va1 and the voltage Va2 is larger than or equal to the threshold H. Thus, the comparator CMP ceases to output a voltage. However, the inverter circuit element 81 exists between the gate electrode Vg3A and the comparator CMP. Thus, the output signal from the comparator CMP is inverted. Accordingly, the gate electrode Vg3A is applied with a voltage. Thus, the third switching element FET3A is turned off, and the gate electrode 50a of the first switching element FET1 is not supplied with a voltage higher than or equal to the threshold voltage from the third wiring 503. That is, the first switching element FET1 is turned off.

On the other hand, the comparator CMP does not supply a voltage to the gate electrode Vg3B of the fifth switching element FET3B. This turns on the fifth switching element FET3B. Thus, the gate electrode 50b of the second switching element FET2 is supplied with a voltage higher than or equal to the threshold voltage from the third wiring 503. This turns on the second switching element FET2. In FIG. 18B, this period is denoted as period B.

In the period B, the second switching element FET2 is in the on-state, and the first switching element FET1 is in the off-state. Thus, in the period B, Vf of the rectification element Dig gradually decreases, and Vf of the rectification element Di1 gradually increases. Next, when the difference (Va1−Va2) between the voltage Va1 and the voltage Va2 becomes larger than or equal to the threshold H again, the state returns to the state of the second switching element FET2 being turned off and the first switching element FET1 being turned on as in the period A.

Thus, in the electronic circuit 500H, the first switching element FET1 and the second switching element FET2 are alternately turned on. Accordingly, heat generation is distributed between the first switching element FET1 and the second switching element FET2. This suppresses the on-resistance increase of the switching elements due to heat generation.

The embodiments described above are illustrative only. For instance, the semiconductor device may be a semiconductor device having opposite polarity with n-type and p-type being interchanged. The respective gate electrodes of the first to seventh switching elements may have different threshold potentials.

In the embodiments described above, the term “on” in “a portion A is provided on a portion B” may refer to not only the case where the portion A is provided on the portion B such that the portion A is in contact with the portion B but also the case where the portion A is provided above the portion B such that the portion A is not in contact with the portion B. Furthermore, “a portion A is provided on a portion B” may refer to the case where the portion A and the portion B are inverted and the portion A is located below the portion B and the case where the portion A and the portion B are laterally juxtaposed. This is because, even when the semiconductor device according to the embodiment is rotated, the structure of the semiconductor device is not changed by the rotation.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first electrode;
a second electrode;
a first semiconductor region of a first conductivity type provided between the first electrode and the second electrode, and the first semiconductor region including a first region and a second region;
a second semiconductor region of a second conductivity type provided between the first semiconductor region and the second electrode in the first region;
a third semiconductor region of the first conductivity type provided between the second semiconductor region and the second electrode, and the third semiconductor region having a higher impurity concentration than the first semiconductor region;
a third electrode being in contact with the first semiconductor region, the second semiconductor region, and the third semiconductor region via a first insulating film;
an element part configured to detect heat released from at least one of the first semiconductor region, the second semiconductor region, and the third semiconductor region;
a fourth semiconductor region of the second conductivity type provided between the first semiconductor region and the second electrode in the second region;
a fifth semiconductor region of the first conductivity type provided between the fourth semiconductor region and the second electrode, and the fifth semiconductor region having a higher impurity concentration than the first semiconductor region; and
a fourth electrode being in contact with the first semiconductor region, the fourth semiconductor region, and the fifth semiconductor region via a second insulating film.

2. The device according to claim 1, wherein distance between the first region and the element part is shorter than distance between the second region and the element part.

3. The device according to claim 1, wherein
the second electrode includes a first electrode part and a second electrode part,
the second semiconductor region is provided between the first semiconductor region and the first electrode part,
the third semiconductor region is provided between the second semiconductor region and the first electrode part,
the fourth semiconductor region is provided between the first semiconductor region and the second electrode part, and
the fifth semiconductor region is provided between the fourth semiconductor region and the second electrode part.

4. The device according to claim 1, wherein
the first semiconductor region has a first surface and a second surface on opposite side of the first surface, and
the element part includes:
a sixth semiconductor region of the first conductivity type provided from the first surface toward the second surface of the first semiconductor region;
a fifth electrode electrically connected to the sixth semiconductor region;
a seventh semiconductor region of the second conductivity type provided from the first surface toward the second surface of the first semiconductor region, and the seventh semiconductor region being in contact with the sixth semiconductor region; and
a sixth electrode electrically connected to the seventh semiconductor region.

5. The device according to claim 1, further comprising:
an insulating layer provided above the first semiconductor region,
wherein the element part includes:
a sixth semiconductor region of the first conductivity type provided above the first semiconductor region, and the sixth semiconductor region being provided in the insulating layer;
a fifth electrode electrically connected to the sixth semiconductor region;
a seventh semiconductor region of the second conductivity type provided above the first semiconductor region, the seventh semiconductor region being in contact with the sixth semiconductor region, and the seventh semiconductor region being provided in the insulating layer; and
a sixth electrode electrically connected to the seventh semiconductor region.

6. The device according to claim 1, further comprising:
a seventh electrode being in contact with the first semiconductor region via a third insulating film between the third electrode and the first electrode; and
an eighth electrode being in contact with the first semiconductor region via a fourth insulating film between the fourth electrode and the first electrode.

7. The device according to claim 1, further comprising:
an eighth semiconductor region of the first conductivity type provided from a first surface toward a second surface of the first semiconductor region;
a ninth semiconductor region and a tenth semiconductor region of the second conductivity type provided on the eighth semiconductor region;
a ninth electrode electrically connected to the ninth semiconductor region;
a tenth electrode electrically connected to the tenth semiconductor region; and
an eleventh electrode being in contact with the eighth semiconductor region, the ninth semiconductor region, and the tenth semiconductor region via a fifth insulating film,
wherein the ninth electrode is electrically connected to the fourth electrode.

8. The device according to claim 1, further comprising:
a tenth semiconductor region of the second conductivity type between the first electrode and the first semiconductor region, and the tenth semiconductor region having a higher impurity concentration than the second semiconductor region and the fourth semiconductor region.

9. The device according to claim 1, wherein the third electrode and the fourth electrode are arranged alternately in a second direction crossing a first direction from the first electrode toward the second electrode.

10. The device according to claim 1, wherein the second semiconductor region and the fourth semiconductor region are provided continuously between the first semiconductor region and the second electrode.

11. A semiconductor module comprising:
a substrate;
a semiconductor device including a first electrode; a second electrode; a first semiconductor region of a first conductivity type provided between the first electrode and the second electrode and including a first region and a second region; a second semiconductor region of a second conductivity type provided between the first semiconductor region and the second electrode in the first region; a third semiconductor region of the first conductivity type provided between the second semiconductor region and the second electrode and having a higher impurity concentration than the first semiconductor region; a third electrode being in contact with the first semiconductor region, the second semiconductor region, and the third semiconductor region via a first insulating film; an element part configured to detect heat released from at least one of the first semiconductor region, the second semiconductor region, and the third semiconductor region in the first region; a fourth semiconductor region of the second conductivity type provided between the first semiconductor region and the second electrode in the second region; a fifth semiconductor region of the first conductivity type provided between the fourth semiconductor region and the second electrode and having a higher impurity concentration than the first semiconductor region; and a fourth electrode being in contact with the first semiconductor region, the fourth semiconductor region, and the fifth semiconductor region via a second insulating film;
a first electrode terminal electrically connected to the substrate;
a second electrode terminal electrically connected to the second electrode of the semiconductor device; and
a third electrode terminal electrically connected to the third electrode of the semiconductor device and electrically connectable to the fourth electrode of the semiconductor device.

12. The module according to claim 11, wherein distance between the first region and the element part is shorter than distance between the second region and the element part.

13. The module according to claim 11, further comprising:
a tenth semiconductor region of the second conductivity type between the first electrode and the first semiconductor region, and the tenth semiconductor region having a higher impurity concentration than the second semiconductor region and the fourth semiconductor region.

14. An electronic circuit comprising:
a first wiring supplied with a first potential;
a second wiring supplied with a second potential different from the first potential;
a third wiring supplied with a third potential different from the first potential and the second potential;
a first switching element including a first gate electrode connected to the third wiring, the first switching element being connected between the first wiring and the second wiring, and a conduction between the first wiring and the second wiring being possible by supply of the third potential to the first gate electrode;
a second switching element including a second gate electrode, the second switching element being connected in parallel with the first switching element between the first wiring and the second wiring, and a conduction between the first wiring and the second wiring being possible when the second gate electrode being electrically contacted to the third wiring;
an element including an anode electrode and a cathode electrode, the element being configured to detect heat released from the first switching element, the anode electrode being connected to the third wiring, and the cathode electrode being connected to the second wiring;
a third switching element including a third gate electrode, and the third switching element being connected between the third wiring and the second gate electrode; and
a first control element being capable of sensing potential difference between voltage applied to the element and a reference voltage, the first control element turning on or turning off the third switching element in response to the potential difference, the first control element making a path between the first wiring and the second wiring electrically continuous or discontinuous through the second switching element.

15. The circuit according to claim 14, wherein the first switching element and the element are provided on a same semiconductor substrate.

16. The circuit according to claim 14, further comprising:
a fourth switching element including a fourth gate electrode, the fourth switching element being connected in parallel with the first switching element between the first wiring and the second wiring, and a conduction between the first wiring and the second wiring being possible when the fourth gate electrode being electrically contacted to the third wiring;
a fifth switching element including a fifth gate electrode, and the fifth switching element being connected between the third wiring and the fourth gate electrode; and
a second control element turning on or off the fifth switching element in response to the potential difference, and the second control element making a path between the first wiring and the second wiring electrically continuous or discontinuous through the fourth switching element.

17. The circuit according to claim 14, wherein
the third switching element includes a p-channel transistor,
the first control element supplies a voltage to a gate of the transistor when the application voltage is higher than or equal to the reference voltage and turns off the third switching element, and
the first control element does not supply the voltage to the gate of the transistor when the application voltage is lower than the reference voltage and turns on the third switching element.

18. The circuit according to claim 14, wherein
the third switching element includes a p-channel transistor,
the first control element supplies a voltage to a gate of the transistor when the application voltage is higher than or equal to the reference voltage and turns on the third switching element, and
the first control element does not supply the voltage to the gate of the transistor when the application voltage is lower than the reference voltage and turns off the third switching element.

19. The circuit according to claim 14, wherein a resistance element is connected between the third wiring and the first gate electrode of the first switching element.

20. The circuit according to claim 14, wherein a resistance element is connected between the third switching element and the second gate electrode of the second switching element.
